(19) United States
(12) Patent Application Publication
(10) Pub. No.: US 2025/0007494 A1
(43) Pub. Date: Jan. 2, 2025

(54) ACOUSTIC WAVE DEVICE USING THIN MASSLOADING IN A RAISED FRAME STRUCTURE

(71) Applicant: Skyworks Global Pte. Ltd., Singapore (SG)

(72) Inventors: Jiansong Liu, Fremont, CA (US); Kwang Jae Shin, Yongin (KR); Li Chen, Irvine, CA (US)

(21) Appl. No.: 18/758,878

(22) Filed: Jun. 28, 2024

Related U.S. Application Data
(60) Provisional application No. 63/524,579, filed on Jun. 30, 2023.

(51) Int. Cl. H03H 9/17; H03H 9/02; H03H 9/56

(52) U.S. Cl. CPC H03H 9/173; H03H 9/02118; H03H 9/568

(57) ABSTRACT

A bulk acoustic wave device includes a first electrode, a second electrode, and a piezoelectric layer positioned between the first electrode and the second electrode. A first raised frame structure outside of a middle area of an active domain of the bulk acoustic wave device, the raised frame structure including a first raised frame layer positioned between the first electrode and the second electrode and having a lower acoustic impedance than the first electrode. A mass-loading layer is disposed between the first raised frame layer and the piezoelectric layer. A thickness of the mass-loading layer is less than 50% of the thickness of the first raised frame layer. The first raised frame layer extends further into the active domain of the bulk acoustic wave device than the mass-loading layer.

### INCORPORATION BY REFERENCE TO ANY PRIORITY APPLICATIONS

Any and all applications for which a foreign or domestic priority claim is identified in the Application Data Sheet as filed with the present application are hereby incorporated by reference under 37 CFR 1.57.

### BACKGROUND

### Field

The present disclosure generally relates to bulk acoustic resonators and to acoustic wave filters employing such bulk acoustic resonators.

### Description of the Related Technology

A bulk acoustic wave (BAW) resonator is a device having a piezoelectric material between two electrodes. When an electromagnetic signal is applied to one of the electrodes, an acoustic wave is generated in the piezoelectric material and propagates to the other electrode. Depending on the thickness of the piezoelectric material, resonance of such an acoustic wave is established, and on the other electrode, an electromagnetic signal having a frequency corresponding to the resonant acoustic wave is generated. Thus, such a BAW resonator can be utilized in acoustic wave filters to provide filtering functionality for an electromagnetic signal such as a radio-frequency (RF) signal.

Acoustic wave filters can be implemented in radio frequency electronic systems. For instance, filters in a radio frequency front end of a mobile phone can include one or more acoustic wave filters. A plurality of acoustic wave filters can be arranged as a multiplexer. For instance, two acoustic wave filters can be arranged as a duplexer.

An acoustic wave filter can include a plurality of resonators arranged to filter a radio frequency signal. Example acoustic wave filters include surface acoustic wave (SAW) filters and BAW filters. BAW filters include BAW resonators. In many applications, the piezoelectric material for the piezoelectric layer between the electrodes is relatively thin and implemented as a film. Thus, a BAW resonator is sometimes referred to as a thin-film bulk acoustic resonator (TFBAR) or as a film bulk acoustic resonator (FBAR).

For BAW devices, achieving a high quality factor (Q) is generally desirable. However, Q can vary in BAW devices due to variations in manufacturing and/or for other reasons.

### SUMMARY OF CERTAIN INVENTIVE CONCEPTS

The innovations described in the claims each have several aspects, no single one of which is solely responsible for its desirable attributes. Without limiting the scope of the claims, some prominent features of this disclosure will now be briefly described.

In some aspects, the techniques described herein relate to a bulk acoustic wave device including: a first electrode, a second electrode, and a piezoelectric layer positioned between the first electrode and the second electrode; a first raised frame layer outside of a middle area of an active domain of the bulk acoustic wave device, positioned between the first electrode and the second electrode and having a lower acoustic impedance than the first electrode; and a second layer disposed between the first raised frame layer and the piezoelectric layer, the second layer thinner than the first raised frame layer and formed of a different material than the first raised frame layer, and the first raised frame layer.

In some aspects, the techniques described herein relate to a bulk acoustic wave device wherein the first raised frame layer is a silicon dioxide layer.

In some aspects, the techniques described herein relate to a bulk acoustic wave device wherein the acoustic impedance of the first raised frame layer is lower than an acoustic impedance of the piezoelectric layer.

In some aspects, the techniques described herein relate to a bulk acoustic wave device wherein the first electrode includes at least one of molybdenum, tungsten, ruthenium, platinum, or iridium.

In some aspects, the techniques described herein relate to a bulk acoustic wave device wherein the first raised frame layer is positioned between the piezoelectric layer and the first electrode.

In some aspects, the techniques described herein relate to a bulk acoustic wave device wherein the first raised frame layer extends further into the active domain of the bulk acoustic wave device than the second layer.

In some aspects, the techniques described herein relate to a bulk acoustic wave device wherein the second layer includes at least one of titanium, ruthenium, molybdenum, tungsten, platinum, aluminum, iridium, chromium, cobalt, nickel, copper, gold, or any suitable alloy thereof.

In some aspects, the techniques described herein relate to a bulk acoustic wave device wherein the second layer includes at least one of aluminum oxide, silicon carbide, aluminum nitride, titanium nitride, silicon nitride, silicon oxynitride, or diamond like carbon.

In some aspects, the techniques described herein relate to a bulk acoustic wave device wherein the second layer provides mass loading.

In some aspects, the techniques described herein relate to a packaged module including: a packaging substrate; an acoustic wave filter on the packaging substrate and configured to filter a radio frequency signal, the acoustic wave filter including a bulk acoustic wave device, the bulk acoustic wave device including a first raised frame layer outside of a middle area of an active region of the bulk acoustic wave device, the first raised frame layer positioned between an electrode and a piezoelectric layer, the first raised frame layer having a lower acoustic impedance than the electrode, and a mass-loading layer disposed between the first raised frame layer and the piezoelectric layer, the mass-loading layer thinner than the first raised frame layer and formed of a different material than the first raised frame layer, and the first raised frame layer; and a radio frequency component electrically coupled to the acoustic wave filter and positioned on the packaging substrate, the acoustic wave filter and the radio frequency component being enclosed within a common package.

In some aspects, the techniques described herein relate to a multiplexer wherein the common node is configured to receive a carrier aggregation signal including at least a first carrier associated with the first passband and a second carrier associated with the second passband.

In some aspects, the techniques described herein relate to a multiplexer wherein the electrode includes at least one of molybdenum, tungsten, ruthenium, platinum, or iridium.

In some aspects, the techniques described herein relate to a multiplexer wherein the first raised frame layer extends further into the active domain of the bulk acoustic wave device than the mass-loading layer.

In some aspects, the techniques described herein relate to a multiplexer wherein the mass-loading layer includes at least one of titanium, ruthenium, molybdenum, tungsten, platinum, aluminum, iridium, chromium, cobalt, nickel, copper, gold, or any suitable alloy thereof.

In some aspects, the techniques described herein relate to a packaged module wherein the mass-loading layer includes at least one of aluminum oxide, silicon carbide, aluminum nitride, titanium nitride, silicon nitride, silicon oxynitride, or diamond like carbon.

In some aspects, the techniques described herein relate to a film bulk acoustic wave resonator device including: a substrate; first and second metal layers implemented over the substrate; a piezoelectric layer between the first and second metal layers; and a first raised frame layer outside of a middle area of an active domain of the bulk acoustic wave device, positioned between the first electrode and the second electrode, having a lower acoustic impedance than the first electrode, and having a non-gradient portion and a gradient portion; and a second layer disposed between the non-gradient portion of the first raised frame layer and the piezoelectric layer, the mass-loading layer thinner than the first raised frame layer and formed of a different material than the first raised frame layer, and the first raised frame layer.

In some aspects, the techniques described herein relate to a film bulk acoustic wave resonator device wherein the first raised frame layer is a silicon dioxide layer.

In some aspects, the techniques described herein relate to a film bulk acoustic wave resonator device wherein the acoustic impedance of the first raised frame layer is lower than an acoustic impedance of the piezoelectric layer.

In some aspects, the techniques described herein relate to a film bulk acoustic wave resonator device wherein the second layer includes at least one of titanium, ruthenium, molybdenum, tungsten, platinum, aluminum, iridium, chromium, cobalt, nickel, copper, gold, or any suitable alloy thereof.

In some aspects, the techniques described herein relate to a film bulk acoustic wave resonator device wherein the second layer includes at least one of aluminum oxide, silicon carbide, aluminum nitride, titanium nitride, silicon nitride, silicon oxynitride, or diamond like carbon.

In some aspects, the techniques described herein relate to a bulk acoustic wave device including: a first electrode, a second electrode, and a piezoelectric layer positioned between the first electrode and the second electrode; a first raised frame structure outside of a middle area of an active domain of the bulk acoustic wave device, the raised frame structure including a first raised frame layer positioned between the first electrode and the second electrode and having a lower acoustic impedance than the first electrode; and a mass-loading layer disposed between the first raised frame layer and the piezoelectric layer, the thickness of the mass-loading layer being less than 50% of the thickness of the first raised frame layer, the first raised frame layer extending further into the active domain of the bulk acoustic wave device than the mass-loading layer.

In some aspects, the techniques described herein relate to a bulk acoustic wave device wherein the first raised frame layer is a silicon dioxide layer.

In some aspects, the techniques described herein relate to a bulk acoustic wave device wherein the acoustic impedance of the first raised frame layer is lower than an acoustic impedance of the piezoelectric layer.

In some aspects, the techniques described herein relate to a bulk acoustic wave device wherein the first electrode includes at least one of molybdenum, tungsten, ruthenium, platinum, or iridium.

In some aspects, the techniques described herein relate to a bulk acoustic wave device wherein the first raised frame layer is positioned between the piezoelectric layer and the first electrode.

In some aspects, the techniques described herein relate to a bulk acoustic wave device wherein the mass-loading layer includes at least one of titanium, ruthenium, molybdenum, tungsten, platinum, aluminum, iridium, chromium, cobalt, nickel, copper, gold, or any suitable alloy thereof.

In some aspects, the techniques described herein relate to a bulk acoustic wave device wherein the mass-loading layer includes at least one of aluminum oxide, silicon carbide, aluminum nitride, titanium nitride, silicon nitride, silicon oxynitride, or diamond like carbon.

In some aspects, the techniques described herein relate to a multiplexer including: a first filter having a first passband, the first filter including a bulk acoustic wave device, the bulk acoustic wave device including a raised frame structure outside of a middle area of an active region of the bulk acoustic wave device, the raised frame structure including a first raised frame layer positioned between an electrode and a piezoelectric layer, the first raised frame layer having a lower acoustic impedance than the electrode, and a mass-loading layer disposed between the first raised frame layer and the piezoelectric layer, the thickness of the mass-loading layer being less than 50% of the thickness of the first raised frame layer, the first raised frame layer extending further into the active domain of the bulk acoustic wave device than the mass-loading layer; and a second filter having a second passband, the second filter coupled to the first filter at a common node, and the raised frame structure configured to move a raised frame mode of the bulk acoustic wave device away from the second passband.

In some aspects, the techniques described herein relate to a multiplexer wherein the common node is configured to receive a carrier aggregation signal including at least a first carrier associated with the first passband and a second carrier associated with the second passband.

In some aspects, the techniques described herein relate to a multiplexer wherein the electrode includes at least one of molybdenum, tungsten, ruthenium, platinum, or iridium.

In some aspects, the techniques described herein relate to a multiplexer wherein the mass-loading layer includes at least one of titanium, ruthenium, molybdenum, tungsten, platinum, aluminum, iridium, chromium, cobalt, nickel, copper, gold, or any suitable alloy thereof.

In some aspects, the techniques described herein relate to a multiplexer wherein the mass-loading layer includes at least one of aluminum oxide, silicon carbide, aluminum nitride, titanium nitride, silicon nitride, silicon oxynitride, or diamond like carbon.

In some aspects, the techniques described herein relate to a packaged module including: a packaging substrate; an acoustic wave filter on the packaging substrate and configured to filter a radio frequency signal, the acoustic wave filter including a bulk acoustic wave device, the bulk acoustic wave device including a raised frame structure outside of a middle area of an active region of the bulk acoustic wave device, the raised frame structure including a first raised frame layer positioned between an electrode and a piezoelectric layer, the first raised frame layer having a lower acoustic impedance than the electrode, and a mass-loading layer disposed between the first raised frame layer and the piezoelectric layer, the thickness of the mass-loading layer being less than 50% of the thickness of the first raised frame layer, the first raised frame layer extending further into the active domain of the bulk acoustic wave device than the mass-loading layer; and a radio frequency component electrically coupled to the acoustic wave filter and positioned on the packaging substrate, the acoustic wave filter and the radio frequency component being enclosed within a common package.

In some aspects, the techniques described herein relate to a film bulk acoustic wave resonator device including: a substrate; first and second metal layers implemented over the substrate; a piezoelectric layer between the first and second metal layers; and a gradient raised frame structure outside of a middle area of an active domain of the bulk acoustic wave device, the gradient raised frame structure including a first raised frame layer positioned between the first electrode and the second electrode, having a lower acoustic impedance than the first electrode, and having a non-gradient portion and a gradient portion; and a mass-loading layer disposed between the non-gradient portion of the first raised frame layer and the piezoelectric layer, the thickness of the mass-loading layer being less than 50% of the thickness of the non-gradient portion of the first raised frame layer, the first raised frame layer extending further into the active domain of the bulk acoustic wave device than the mass-loading layer.

In some aspects, the techniques described herein relate to a film bulk acoustic wave resonator device wherein the first raised frame layer is a silicon dioxide layer.

In some aspects, the techniques described herein relate to a film bulk acoustic wave resonator device wherein the acoustic impedance of the first raised frame layer is lower than an acoustic impedance of the piezoelectric layer.

In some aspects, the techniques described herein relate to a film bulk acoustic wave resonator device wherein the mass-loading layer includes at least one of titanium, ruthenium, molybdenum, tungsten, platinum, aluminum, iridium, chromium, cobalt, nickel, copper, gold, or any suitable alloy thereof.

In some aspects, the techniques described herein relate to a film bulk acoustic wave resonator device wherein the mass-loading layer includes at least one of aluminum oxide, silicon carbide, aluminum nitride, titanium nitride, silicon nitride, silicon oxynitride, or diamond like carbon.

For purposes of summarizing the disclosure, certain aspects, advantages and novel features of the inventions have been described herein. It is to be understood that not necessarily all such advantages may be achieved in accordance with any particular embodiment of the invention. Thus, the invention may be embodied or carried out in a manner that achieves or optimizes one advantage or group of advantages as taught herein without necessarily achieving other advantages as may be taught or suggested herein.

### BRIEF DESCRIPTION OF THE DRAWINGS

FIG. 1 is a cross sectional view of a dual raised frame bulk acoustic wave device according to an embodiment.

FIG. 2 is a cross sectional view of a dual raised frame bulk acoustic wave device according to another embodiment.

FIG. 3 is a cross sectional view of a dual raised frame bulk acoustic wave device according to another embodiment.

FIG. 4 is a cross sectional view of a dual raised frame bulk acoustic wave device according to another embodiment.

FIG. 5 is a cross sectional view of a dual raised frame bulk acoustic wave device according to another embodiment.

FIG. 6 is a cross sectional view of a dual raised frame bulk acoustic wave device according to another embodiment.

FIG. 7 is a cross sectional view of a dual raised frame bulk acoustic wave device according to another embodiment.

FIG. 8 is a cross sectional view of a dual raised frame bulk acoustic wave device including one or more gradient raised frames according to another embodiment.

FIG. 9 is a cross sectional view of a dual raised frame bulk acoustic wave device including one or more gradient raised frames according to another embodiment.

FIG. 10 is a cross sectional view of a dual raised frame bulk acoustic wave device including one or more gradient raised frames according to another embodiment.

FIG. 11 is a cross sectional view of a dual raised frame bulk acoustic wave device including one or more gradient raised frames according to another embodiment.

FIG. 12 is a cross sectional view of a dual raised frame bulk acoustic wave device including one or more gradient raised frames according to another embodiment.

FIG. 13A illustrates exemplary Q factor simulation results for a conventional dual raised frame bulk acoustic wave device.

FIG. 13B illustrates exemplary Q factor simulation results for a dual raised frame bulk acoustic wave device with a Ti mass loading layer.

FIG. 13C illustrates exemplary Q factor simulation results for a dual raised frame bulk acoustic wave device with a Ru mass loading layer.

FIG. 13D illustrates exemplary Q factor simulation results for a dual raised frame bulk acoustic wave device with a Ti mass loading layer having a thickness of 25 nm.

FIG. 13E illustrates exemplary Q factor simulation results for a dual raised frame bulk acoustic wave device with a Ti mass loading layer having a thickness of 50 nm.

FIG. 13F illustrates exemplary Q factor simulation results for a dual raised frame bulk acoustic wave device with a Ti mass loading layer having a thickness of 100 nm.

FIG. 14A is a cross sectional view of a dual raised frame bulk acoustic wave device with an extended raised frame layer according to another embodiment.

FIG. 14B is a cross sectional view of a dual raised frame bulk acoustic wave device with a slanted raised frame layer according to another embodiment.

FIG. 15 is a schematic diagram of an example of an acoustic wave ladder filter.

FIG. 16 is a schematic diagram of an example of a multiplexer.

FIG. 17 is a schematic block diagram of a module that includes an antenna switch and duplexers that include one or more multi-layer raised frame bulk acoustic wave devices.

FIG. 18A is a schematic block diagram of a module that includes a power amplifier, a radio frequency switch, and duplexers that include one or more multi-layer raised frame bulk acoustic wave device.

FIG. 18B is a schematic block diagram of a module that includes a low noise amplifier, a radio frequency switch, and acoustic wave filters t include one or more multi-layer raised frame bulk acoustic wave devices.

FIG. 19 is a schematic block diagram of a module that includes a power amplifier, a radio frequency switch, a duplexer that includes one or more multi-layer raised frame bulk acoustic wave device.

FIG. 20 is a schematic block diagram of a wireless communication device that includes filters that include one or more multi-layer raised frame bulk acoustic wave devices.

FIG. 21 is a schematic block diagram of another wireless communication device that includes filters that include one or more multi-layer raised frame bulk acoustic wave devices.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Described herein are various examples related to bulk acoustic wave (BAW) resonators and related devices having an improved quality factor Q. For example, BAW resonators and related devices described herein can have increased mode reflection and reduced mode conversion. Although such examples are described in the context of BAW resonators, it will be understood that one or more features of the present disclosure can also be implemented in other types of resonators, including devices that are similar to BAW resonators but referred to in different terms.

For developing high performance BAW filters, reducing insertion loss and decreasing Gamma loss is generally desirable. To achieve a low insertion loss, BAW resonators typically have a high quality factor (Q). To achieve a high Q, a raised frame structure, which can be referred to as a border ring, can block lateral energy leakage from an active domain of a BAW resonator to a passive domain of the BAW resonator. A raised frame can improve Q, although it may not be able to trap all leakage energy. The raised frame can generate a relatively large spurious mode, which can be referred to as raised frame mode, below a main resonant frequency of a BAW resonator. This can cause Gamma degradation in carrier aggregation bands for a filter. Gamma can refer to a reflection coefficient. A low Gamma loss can be achieved with a raised frame spurious mode (RaF mode) away from carrier aggregation bands.

BAW devices can include single-layer or multi-layer raised frame structures. A raised frame structure can reduce lateral energy leakage from a main acoustically active region of the bulk acoustic wave device. A BAW device can include a single-layer raised frame structure that can achieve a relatively high quality factor (Q) in a region below a resonant frequency (fs). The single-layer raised frame structure can include a single-layer gradient raised frame structure. The single-layer raised frame structure can include a single-layer multi-gradient (dual-gradient) raised frame structure. In certain BAW devices, the gradient (slope or taper) of the raised frame structure can be caused due to a manufacturing artifact. For example, the gradient may be formed during an etching process.

Generally, leakage of laterally propagating modes out of an active region of a BAW resonator can cause the quality factor Q to decrease. In addition, mode conversion from the main mode to lateral modes can also cause the quality factor Q to decrease. A raised frame structure can act as a reflector that reflects lateral modes back to the active region and can improve the quality factor Q.

However, having only one raised frame may not be sufficient to reflect all the lateral modes. In order to strengthen the reflection and achieve maximum mode reflection, it can be necessary to form multiple reflectors, such as two or more raised frames, for example, by forming different unmatched acoustic impedance interfaces. However, forming multiple reflectors can create a number of discontinuous boundaries, which can increase mode conversion.

Although embodiments disclosed herein may be discussed with reference to a dual raised frame structure with two raised frame layers, any suitable principles and advantages discussed herein can be applied to a multi-layer raised frame structure that includes two or more raised frame layers.

Example bulk acoustic resonators with dual raised frame layers will now be discussed. Any suitable principles and advantages of these dual raised frame layers can be implemented together with each other in a multi-layer raised frame bulk acoustic wave device.

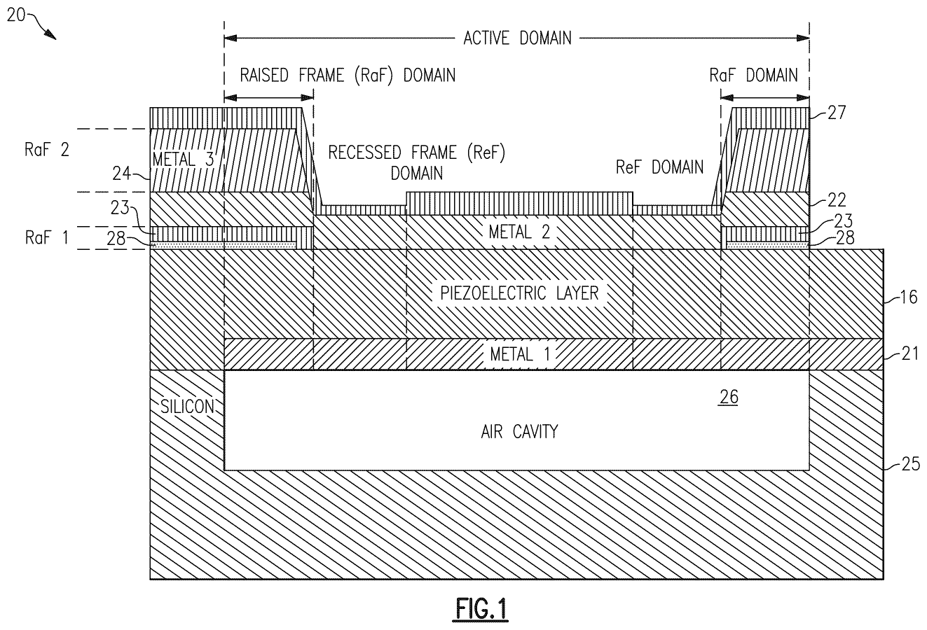

FIG. 1 is a cross sectional view of a dual raised frame bulk acoustic wave device 20 according to an embodiment. As illustrated, the dual raised frame bulk acoustic device 20 includes a piezoelectric layer 16, a first electrode 21, a second electrode 22, a first raised frame layer 23, a second raised frame layer 24, a silicon substrate 25, an air cavity 26, a silicon dioxide layer 27, and a mass-loading layer 28.

The piezoelectric layer 16 is disposed between the first electrode 21 and the second electrode 22. The piezoelectric layer 16 can be an aluminum nitride (AlN) layer or any other suitable piezoelectric layer. An active region or active domain of the bulk acoustic wave device 20 is defined by the portion of the piezoelectric layer 16 that overlaps with both the first electrode 21 and the second electrode 22. The first electrode 21 can have a relatively high acoustic impedance. For example, the first electrode 21 can include molybdenum (Mo), tungsten (W), ruthenium (Ru), chromium (Cr), iridium (Ir), platinum (Pt), Ir/Pt, or any suitable alloy and/or combination thereof. Similarly, the second electrode 22 can have a relatively high acoustic impedance. The second electrode 22 can be formed of the same material as the first electrode 21 in certain instances. For example, the second electrode 22 can include Mo, W, Ru, Cr, Ir, Pt, Ir/Pt, or any suitable alloy and/or combination thereof.

The bulk acoustic wave device 20 includes a raised frame (RaF) domain around the perimeter of the active region or active domain of the bulk acoustic wave device 20. The RaF domain can be referred to as a border ring in certain instances. A dual raised frame structure can be in the RaF domain. The dual raised frame structure is outside of a middle area of the active region of the bulk acoustic wave device 20.

The dual raised frame structure of the bulk acoustic wave device 20 includes the first raised frame layer 23 and the second raised frame layer 24. The first raised frame layer 23 and the second raised frame layer 24 overlap with each other in the active domain of the bulk acoustic wave device 20. The RaF domain of the bulk acoustic wave device 20 is defined by the portion of dual raised frame structure in the active domain of the bulk acoustic wave device 20. At least a portion of the dual raised frame structure is included in the active domain of the bulk acoustic wave device 20.

The dual raised frame structure can improve Q significantly over a bulk acoustic wave device lacking such a raised frame domain, mainly due to highly efficient reflection of lateral energy. The raised frame structure can act as a reflector that reflects lateral modes back into the active domain, thereby improving the quality factor Q.

The first raised frame layer 23 is positioned between the first electrode 21 and the second electrode 22. As illustrated in FIG. 1, the first raised frame layer 23 is positioned between the piezoelectric layer 16 and the second electrode 22. The first raised frame layer 23 is a low acoustic impedance material. The low acoustic impedance material has a lower acoustic impedance than the first electrode 21. The low acoustic impedance material has a lower acoustic impedance than the second electrode 22. The low acoustic impedance material can have a lower acoustic impedance than the piezoelectric layer 16.

As an example, the first raised frame layer 23 can be a silicon dioxide (SiO₂) layer. Because silicon dioxide is already used in a variety of bulk acoustic wave devices, a silicon dioxide first raised frame layer 23 can be relatively easy to manufacture. The first raised frame layer 23 can be a silicon nitride (SiN) layer, a silicon carbide (SiC) layer, or any other suitable low acoustic impedance layer. The first raised frame layer 23 can have a relatively low density. The first raised frame layer 23 can extend beyond the active region of the bulk acoustic wave device 20 as shown in FIG. 1. This can be for manufacturability reasons in certain instances.

The first raised frame layer 23 can reduce an effective electromechanical coupling coefficient (k²) of the raised frame domain of the bulk acoustic wave device 20 relative to a similar device without the first raised frame layer 23. This can reduce excitation strength of a raised frame spurious mode. Moreover, the first raised frame layer 23 can contribute to move the frequency of the raised frame mode relatively far away from the main resonant frequency of the bulk acoustic wave device 20, which can result in no significant effect on a Gamma loss.

In order to even further improve the quality factor Q for a first raised frame layer 23 comprising or consisting of an oxide (such as for example SiO₂), a mass-loading layer 28 is disposed underneath the first raised frame layer 23 and on top of the piezoelectric layer 16. The mass-loading layer 28 has a thickness that is comparably thin with respect to the thickness of the first raised frame layer 23. For example, the thickness of the mass-loading layer 28 may be less than 12%, less than 25%, or less than 50% of the thickness of the first raised frame layer 23. For example, if the first raised frame layer 23 has a thickness of 120 nm, the thickness of the mass-loading layer 28 may be 20 nm, 25 nm, 30 nm, 40 nm, 50 nm, 75 nm, or 100 nm.

The first raised frame layer 23 may extend further into the active domain of the bulk acoustic wave device 20 than the mass-loading layer 28. In other words, the first raised frame layer 23 may fully overlap the mass-loading layer 28 and may entirely separate the mass-loading layer 28 from the second electrode 22.

The material used for forming the mass-loading layer 28 may for example be a metal, such as titanium (Ti), ruthenium (Ru), molybdenum (Mo), tungsten (W), platinum (Pt), aluminum (Al), iridium (Ir), chromium (Cr), cobalt (Co), nickel (Ni), copper (Cu), gold (Au), or any suitable alloy thereof. In other implementations, the mass-loading layer 28 can be formed of another material that is different than that of the raised frame layer 23. In various implementations, the material used for forming the mass-loading layer 28 may for example be a metal oxide layer, a silicon dioxide layer or any other suitable passivation layer. Particular examples for the material used for forming the mass-loading layer 28 may be aluminum oxide, silicon carbide, aluminum nitride, titanium nitride, silicon nitride, silicon oxynitride, or diamond like carbon (DLC).

As illustrated, the second raised frame layer 24 overlaps with the first raised frame layer 23 in the active region of the bulk acoustic wave device 20. The second raised frame layer 24 can be the same material as the second electrode 22. This can be convenient from a manufacturing perspective. The second raised frame layer 24 can be a relatively high density material. For instance, the second raised frame layer 24 can include molybdenum (Mo), tungsten (W), ruthenium (Ru), the like, or any suitable alloy thereof. The second raised frame layer 24 can be a metal layer. Alternatively, the second raised frame layer 24 can be a suitable non-metal material with a relatively high density. The density of the second raised frame layer 24 can be similar or heavier than the density of the second electrode 22. The second raised frame layer 24 can have a relatively high acoustic impedance.

The second raised frame layer 24 increases the height of the bulk acoustic wave device 20 in the raised frame domain. Accordingly, the bulk acoustic wave device 20 has a greater height in the raised frame domain than in other portions of the active domain, such as the middle area of the active domain. Forming the second raised frame layer 24 over the second electrode 22 can be relatively easy from a manufacturing perspective. However, in some other embodiments, a second raised frame layer can be included in a different position in the stack of layers in the raised frame domain.

In the bulk acoustic wave device 20, a silicon dioxide layer 27 is included over the second electrode 22 and the second raised frame layer 24. The silicon dioxide layer 27 can be formed with different thicknesses in different regions of the bulk acoustic wave device 20. For example, as shown in FIG. 1, the silicon dioxide layer 27 is thinner in a recessed frame domain. Any suitable passivation layer can be included in place and/or in addition to the silicon dioxide layer 27.

The dual raised frame bulk acoustic wave device 20 is an FBAR. An air cavity 26 is included below the first electrode 21. The air cavity 26 is defined by the geometry of the first electrode 21 and the silicon substrate 25. Other suitable substrates can alternatively be implemented in place of the silicon substrate 25. One or more layers, such as a passivation layer, can be positioned between the first electrode 21 and the silicon substrate 25.

Although the bulk acoustic wave device 20 is an FBAR, any suitable principles and advantages discussed herein can be applied to a solidly mounted resonator (SMR).

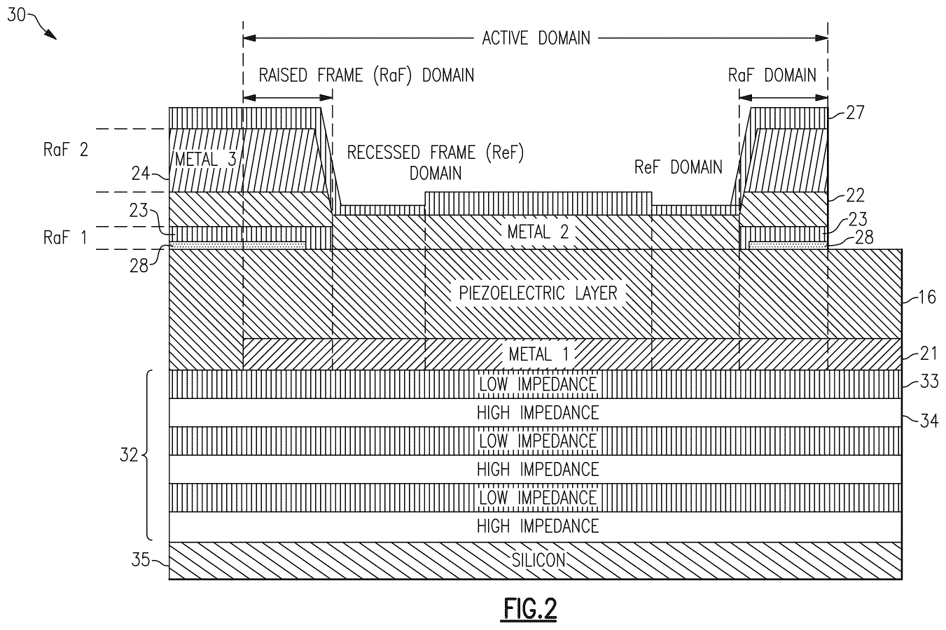

FIG. 2 is a cross sectional view of a dual raised frame bulk acoustic wave device 30 according to an embodiment. The dual raised frame bulk acoustic device 30 is like the dual raised frame bulk acoustic wave device 20 of FIG. 2, except that the bulk acoustic wave device 30 is an SMR instead of an FBAR. In the bulk acoustic wave device 30, a solid acoustic mirror is disposed between the first electrode 21 and a silicon substrate 35. The illustrated acoustic mirror includes acoustic Bragg reflectors 32. The illustrated acoustic Bragg reflectors 32 include alternating low impedance layers 33 and high impedance layers 34. As an example, the Bragg reflectors 32 can include alternating silicon dioxide layers as low impedance layers 33 and tungsten layers as high impedance layers 34. Any other suitable features of an SMR can alternatively or additionally be implemented in a multi-layer raised frame bulk acoustic wave device.

FIG. 3 is a cross sectional view of a dual raised frame bulk acoustic wave device 40 according to an embodiment. The dual raised frame bulk acoustic device 40 is like the dual raised frame bulk acoustic wave device 20 of FIG. 1, except that the silicon dioxide layer 27 is omitted in the bulk acoustic wave device 40 and there is no recessed framed domain in the bulk acoustic wave device 40.

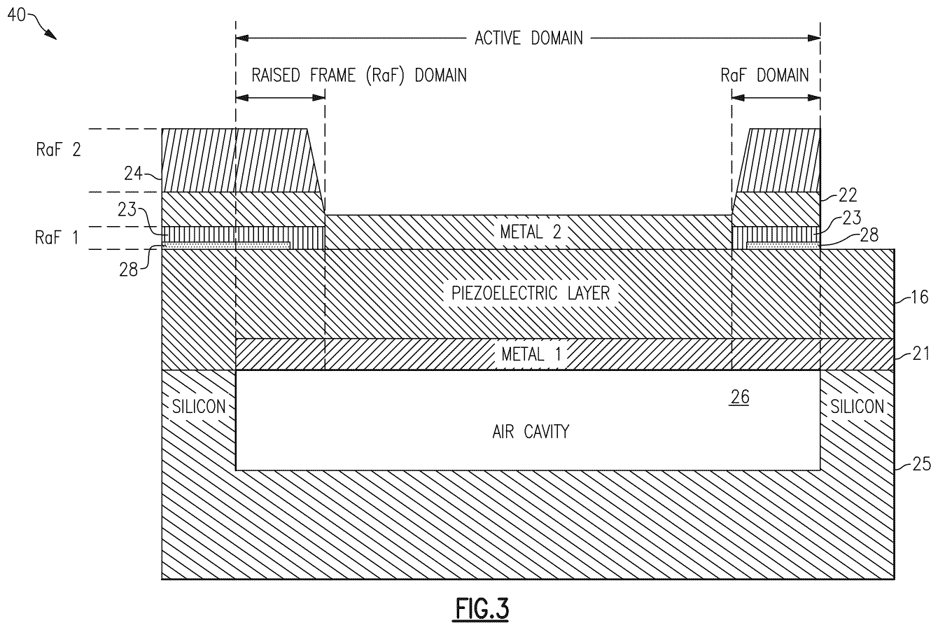

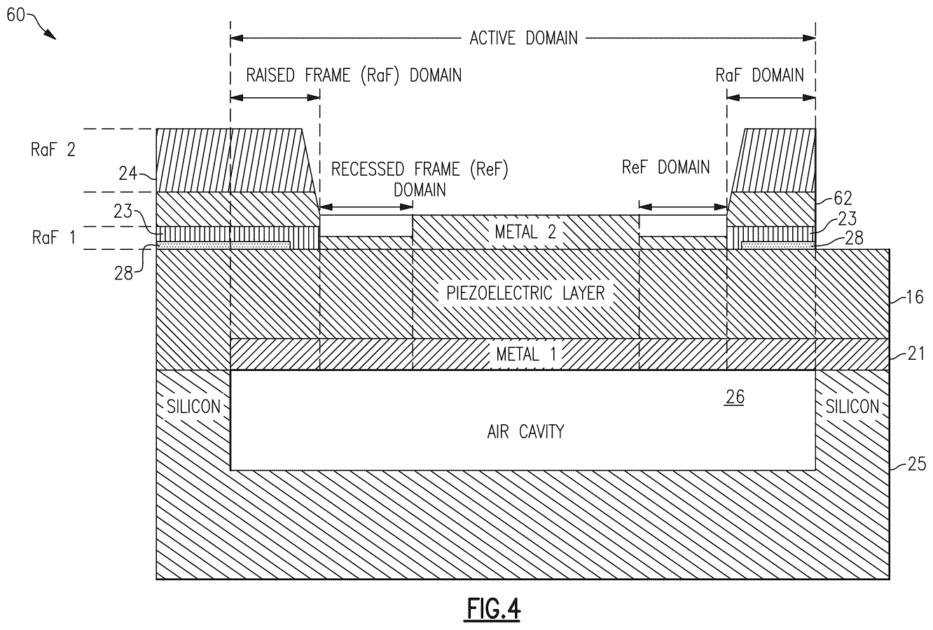

FIG. 4 is a cross sectional view of a dual raised frame bulk acoustic wave device 60 according to an embodiment. The dual raised frame bulk acoustic device 60 is like the dual raised frame bulk acoustic wave device 40 of FIG. 3, except that a second electrode 62 of the bulk acoustic wave device 60 is different than the second electrode 22 of the bulk acoustic wave device 40. The second electrode 62 has different thicknesses in different regions. The region where the second electrode 62 is thinner implements a recessed framed domain in the bulk acoustic wave device 60.

FIG. 5 is a cross sectional view of a dual raised frame bulk acoustic wave device 70 according to an embodiment. The dual raised frame bulk acoustic device 70 is like the dual raised frame bulk acoustic wave device 40 of FIG. 3, except that the bulk acoustic wave device 70 includes two raised frame domains. The bulk acoustic wave device 70 includes a first raised frame layer 73 in a first raised frame domain RaF and a second raised frame domain RaF 3. The first raised frame domain RaF in the bulk acoustic wave device 70 is like the raised frame domain in the bulk acoustic wave device 40 of FIG. 3.

The first raised frame layer 73 and the second raised frame layer 24 are included in the first raised frame domain RaF. The first raised frame layer 73 can include any suitable features of the first raised frame layer 23 of FIG. 1. The first raised frame layer 73 is thinner in the second raised frame domain RaF 3 in which the first raised frame layer 73 and a second electrode 72 are disposed over the piezoelectric layer 16. In particular, the mass-loading layer 28 in this embodiment is implemented only beneath the first raised frame layer 73 in the first raised frame domain RaF, while the portion of the first raised frame layer 73 in the second raised frame domain RaF 3 does not have a mass-loading layer 28 placed between the first raised frame layer 73 and the piezoelectric layer 16.

The second raised frame region RaF 3 can be referred to as a recessed raised frame region. The second electrode 72 has a different shape in cross sectional view than the second electrode 22 of FIG. 3. The second raised frame layer 24 is outside of the second raised frame domain RaF 3. With the first raised frame layer 73, the second raised frame domain RaF 3 has a different acoustic impedance than (1) the middle area of the active region and (2) the first raised frame domain RaF. This can help with spurious mode suppression. The first raised frame region can surround the second raised frame region in plan view in the bulk acoustic wave device 70.

FIG. 6 is a cross sectional view of a dual raised frame bulk acoustic wave device 80 according to an embodiment. In the bulk acoustic wave device 80, a first raised frame layer 83 is positioned between the first electrode 21 and a piezoelectric layer 86. The first raised frame layer 83 is in physical contact with the piezoelectric layer 86 and the first electrode 21. The first raised frame layer 83 can function similarly to the first raised frame layer 23. The first raised frame layer 83 can include any suitable features of the first raised frame layer 23.

In order to even further improve the quality factor Q for the first raised frame layer 83 comprising or consisting of an oxide (such as for example SiO₂), a mass-loading layer 88 is disposed above the first raised frame layer 83 and beneath the piezoelectric layer 86. The mass-loading layer 88 has a thickness that is comparably thin with respect to the thickness of the first raised frame layer 83. For example, the thickness of the mass-loading layer 88 may be less than 12%, less than 25%, or less than 50% of the thickness of the first raised frame layer 83. For example, if the first raised frame layer 83 has a thickness of 120 nm, the thickness of the mass-loading layer 28 may be 20 nm, 25 nm, 30 nm, 40 nm, 50 nm, 75 nm, or 100 nm.

The first raised frame layer 83 may extend further into the active domain of the bulk acoustic wave device 80 than the mass-loading layer 88. In other words, the first raised frame layer 83 may fully overlap the mass-loading layer 88 and may entirely separate the mass-loading layer 88 from the first electrode 21.

The material used for forming the mass-loading layer 88 may for example be a metal, such as titanium (Ti), ruthenium (Ru), molybdenum (Mo), tungsten (W), platinum (Pt), aluminum (Al), iridium (Ir), chromium (Cr), cobalt (Co), nickel (Ni), copper (Cu), gold (Au), or any suitable alloy thereof. In various implementations, the material used for forming the mass-loading layer 88 may be some other material that is different than that of the first raised frame layer 83. In other implementations, the material used for forming the mass-loading layer 88 may for example be a metal oxide layer, a silicon dioxide layer or any other suitable passivation layer. Particular examples for the material used for forming the mass-loading layer 88 may be aluminum oxide, silicon carbide, aluminum nitride, titanium nitride, silicon nitride, silicon oxynitride, or diamond like carbon (DLC).

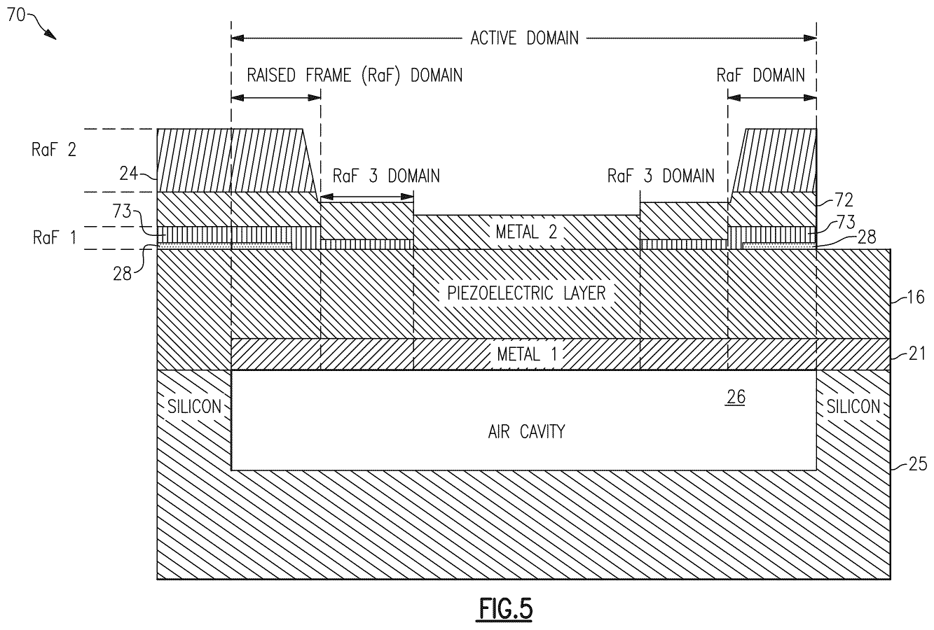

FIG. 7 is a cross sectional view of a dual raised frame bulk acoustic wave device 90 according to an embodiment. The dual raised frame bulk acoustic device 90 is like the dual raised frame bulk acoustic wave device 80 of FIG. 6, except that the second electrode and piezoelectric layer have different shapes in cross sectional view. As shown in FIG. 7, a second electrode 92 can have a planar top surface on which the second raised frame layer 24 is disposed. The planar top surface can make manufacturing easier in certain instances.

FIG. 8 illustrates a side view of a film bulk acoustic wave resonator (FBAR) device 100 including one or more gradient raised frames 140, 150. The FBAR device 100 can include a first metal layer 110, a second metal layer 120, and a piezoelectric layer 130 between the first metal layer 110 and the second metal layer 120. A resonator can be formed by positioning the piezoelectric layer 130 between the first metal layer 110 and the second metal layer 120. In some embodiments, a portion of the piezoelectric layer 130 that overlaps with the first metal layer 110 and the second metal layer 120 can be referred to as a “resonator.” In some embodiments, a metal layer 110, 120 may be referred to as an “electrode.” A radio-frequency (RF) signal can be applied to one of the metal layers 110, 120 and can cause an acoustic wave to be generated in the piezoelectric layer 130. The acoustic wave can travel through the piezoelectric layer 130 and can be converted to an RF signal at the other one of the metal layers 110, 120. In this way, the FBAR device 100 can provide filtering functionality. In the FBAR device 100, acoustic waves can travel in a vertical direction (e.g., perpendicular to the metal layers 110, 120 and the piezoelectric layer 130). For example, the vertical direction can be a Z-direction. Some acoustic waves may travel in a horizontal direction (e.g., parallel to the metal layers 110, 120 and the piezoelectric layer 130). For example, the horizontal direction may be a X-direction, Y-direction, or a combination thereof

The FBAR device 100 can include one or more gradient raised frames (“RaFs”). In the example of FIG. 8, the FBAR device 100 includes a first RaF 140 and a second RaF 150. For example, the first RaF 140 can be on top of the second metal layer 120, and the second RaF 150 can be below the second metal layer 120, between the second metal layer 120 and the piezoelectric layer 130. Each RaF can include a non-gradient RaF portion and a gradient RaF portion. The gradient RaF portion can have a tapering end and a non-tapering end, and the non-tapering end of the gradient RaF portion can be adjacent to the non-gradient RaF portion. As shown in the example of FIG. 8, a RaF can include a non-gradient RaF portion and a gradient RaF portion on each side of a FBAR device 100. The first RaF 140 can include a non-gradient RaF portion 142 and a gradient RaF portion 144. The second RaF 150 can include a non-gradient RaF portion 152 and a gradient RaF portion 154. In certain embodiments, a RaF may only include a gradient RaF portion and not include a non-gradient RaF portion. In some embodiments, a gradient RaF portion of a RaF may be referred to as a “gradient RaF.” A gradient RaF portion can have an angle α, for example, with respect to the horizontal direction. The angle α may also be referred to as a “taper angle.” In some embodiments, the angle α can be less than 90°. In certain embodiments, a gradient RaF portion can have a triangular shape. In other embodiments, a gradient RaF portion can have other polygonal shapes. In some embodiments, the first RaF 140 and the second RaF 150 can have an overlapping region. For example, the gradient RaF portion 144 of the first RaF 140 and the gradient RaF portion 154 of the second RaF 150 can overlap at least in part, for example, in the horizontal direction. The metal layers 110, 120 and the piezoelectric layer 130 can follow the contour or shape of the first RaF 140 and/or the second RaF 150. Accordingly, the metal layers 110, 120 and the piezoelectric layer 130 may include portions that are parallel to the horizontal direction as well as portions that are at an angle with respect to the horizontal direction.

A RaF can be made of or from any suitable material. In some embodiments, a RaF can be made of or from a similar or the same material as the second metal layer 120 and/or the first metal layer 110. For example, a RaF can be made of a heavy material. In certain embodiments, a RaF can be made of or from a low acoustic impedance material. For example, a RaF can be made of silicon dioxide, silicon nitride, etc. A RaF may be made of any low density material. Gradient RaFs can be formed during the manufacturing process for forming a FBAR device (e.g., by deposition process).

In order to even further improve the quality factor Q, a mass-loading layer 156 is disposed beneath the non-gradient RaF portion 152 of the second RaF 150 and on top of the piezoelectric layer 130. This applies in particular to a second RaF 150 that comprises or consists of an oxide (such as for example SiO₂). The mass-loading layer 156 has a thickness that is comparably thin with respect to the thickness of the non-gradient RaF portion 152 of the second RaF 150. For example, the thickness of the mass-loading layer 156 may be less than 12%, less than 25%, or less than 50% of the thickness of the non-gradient RaF portion 152 of the second RaF 150. For example, if the non-gradient RaF portion 152 of the second RaF 150 has a thickness of 120 nm, the thickness of the mass-loading layer 156 may be 20 nm, 25 nm, 30 nm, 40 nm, 50 nm, 75 nm, or 100 nm.

The second RaF 150 may extend further into the active domain of the FBAR device 100 than the mass-loading layer 156. In other words, the mass-loading layer 156 may not or at least not entirely extend beneath the gradient RaF portion 154 so that the gradient RaF portion 154 may entirely separate the mass-loading layer 156 from the second metal layer 120.

The material used for forming the mass-loading layer 156 may for example be a metal, such as titanium (Ti), ruthenium (Ru), molybdenum (Mo), tungsten (W), platinum (Pt), aluminum (Al), iridium (Ir), chromium (Cr), cobalt (Co), nickel (Ni), copper (Cu), gold (Au), or any suitable alloy thereof. In other implementations, the material used for forming the mass-loading layer 156 may for example be a metal oxide layer, a silicon dioxide layer or any other suitable passivation layer. Particular examples for the material used for forming the mass-loading layer 156 may be aluminum oxide, silicon carbide, aluminum nitride, titanium nitride, silicon nitride, silicon oxynitride, or diamond like carbon (DLC). In various implementations, the mass-loading layer 156 may comprise some other material different than that of the second Raf 150.

In the example of FIG. 8, the FBAR device 100 is shown to include two RaFs for illustrative purposes, but the number of RaFs included in the FBAR device 100 can vary as appropriate, depending on the embodiment. For example, in some embodiments, the FBAR device 100 can include one RaF or more than two RaFs. One or more RaFs can be positioned in various configurations. One or more RaFs can be placed at various positions along the vertical direction (e.g., perpendicular to the metal layers 110, 120 and the piezoelectric layer 130). For example, one or more RaFs can be placed at a position above or below the first metal layer 110, above or below the second metal layer 120, between the first metal layer 110 and the second metal layer 120, or any combination thereof. Various examples of configurations of RaFs are described in more detail below.

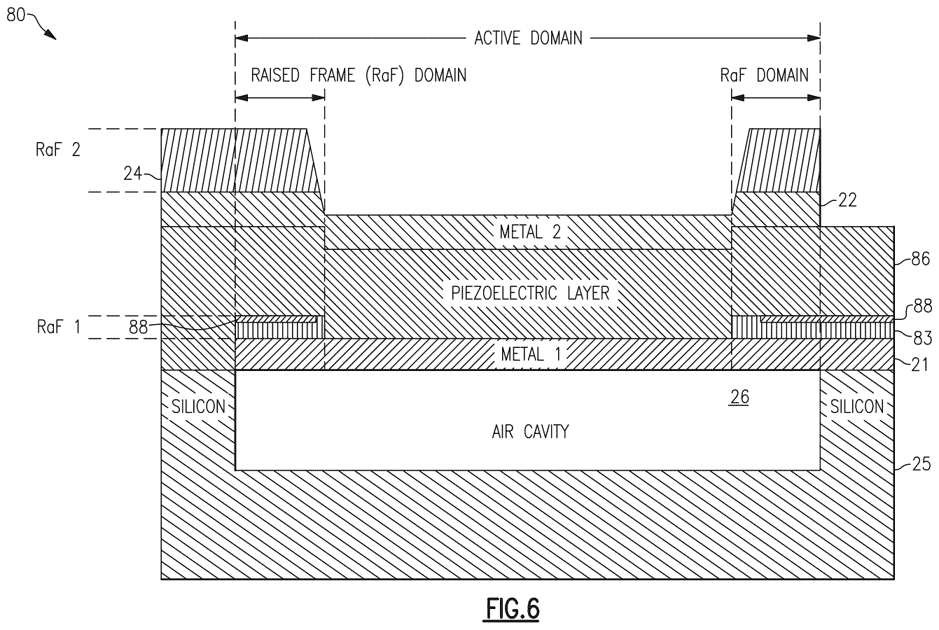

The FBAR device 100 can include an active region 160, for example, between the gradient RaF portion 144 of the first RaF 140 on each side of the FBAR device 100. Main mode waves can travel through the active region 160. For instance, the active region 160 can be a preferred region through which main mode waves can travel. Viewed from a top-down perspective, the active region 160 can have a cylindrical shape, a rectangular shape, or other suitable shapes. In some embodiments, the FBAR device 100 can include a passivation layer above the first RaF 140 as shown in FIG. 9. In certain embodiments, the FBAR device 100 may also include a recessed frame as shown in FIG. 9. In some embodiments, the FBAR device 100 can include a substrate 170 and include an air cavity 180 below the first metal layer 110.

By creating quasi-continuous boundaries, a gradient RaF can increase mode reflection and decrease mode conversion. For example, the quasi-continuous boundaries can act as multiple reflectors to increase mode reflection. The quasi-continuous boundaries can also suppress mode conversion. In this manner, FBAR devices including one or more gradient RaFs can have improved values for the quality factor Q. In some embodiments, lower taper angles for gradient RaFs can be more effective in increasing mode reflection and decreasing mode conversion. For example, the taper angle for a gradient RaF can be less than 45°, 30°, etc. The taper angle can be selected to maximize mode reflection and reduction of mode conversion.

FIG. 9 illustrates a side view of a FBAR device 300 including two gradient raised frames 340, 350, according to certain embodiments. The FBAR device 300 can include a first metal layer 310, a second metal layer 320, and a piezoelectric layer 330 between the first metal layer 310 and the second metal layer 320. In the example of FIG. 9, the FBAR device 300 includes a first RaF 340 and a second RaF 350. The first RaF 340 can be on top of the second metal layer 320, and the second RaF 350 can be below the second metal layer 320, between the second metal layer 320 and the piezoelectric layer 330. The first RaF 340 can include a non-gradient RaF portion 342 and a gradient RaF portion 344. The gradient RaF portion 344 can have an angle α, for example, with respect to the horizontal direction. In some embodiments, the angle α can be less than 90°. The second RaF 350 can include a non-gradient RaF portion 352 and a gradient RaF portion 354. The gradient RaF portion 354 can also have an angle α, for example, with respect to the horizontal direction. In some embodiments, the angle α can be less than 90°. In certain embodiments, the angle α for the gradient RaF portion 344 and the angle α for the gradient RaF portion 354 can be the same. In other embodiments, the angle α for the gradient RaF portion 344 and the angle α for the gradient RaF portion 354 can be different.

In the example of FIG. 9, the length of the gradient RaF portion 344 is greater than the length of the gradient RaF portion 354. For instance, the gradient RaF portion 344 has a longer weight than the gradient RaF portion 354. The second metal layer 320 can follow the contour of the gradient RaF portion 354. The gradient RaF portion 344 can follow the contour of the second metal layer 320. In the example of FIG. 9, the lower or bottom edge of the gradient RaF portion 344 can include a first portion that is parallel to the upper or top edge of the gradient RaF portion 354 and a second portion that is parallel to the horizontal direction. For example, the first portion of the gradient RaF portion 344 can be at an angle with respect to the horizontal direction. The first portion of the gradient RaF portion 344 can have the same length as the gradient RaF portion 354. The lower or bottom edge of the gradient RaF portion 354 can be parallel to the horizontal direction. In the example of FIG. 9, the length of the non-gradient RaF portion 342 and the length of the non-gradient RaF portion 352 can be the same. The non-gradient RaF portion 342 and the non-gradient RaF portion 352 can be aligned, for example, with respect to the vertical direction. The non-tapering end of the gradient RaF portion 344 and the non-tapering end of the gradient RaF portion 354 can also be aligned. In some embodiments, the length of the non-gradient RaF portion 342 and the length of the non-gradient RaF portion 352 may be different. In certain embodiments, the thickness of the RaF 340 and the thickness of the RaF 350 can be the same. In other embodiments, the thickness of the RaF 340 and the thickness of the RaF 350 can be different.

Similar to the embodiment shown in FIG. 8, a mass-loading layer 356 is disposed beneath the non-gradient RaF portion 352 of the second RaF 350 and on top of the piezoelectric layer 330. The mass-loading layer 356 may be implemented with the same properties and characteristics as the mass-loading layer 156 of FIG. 8.

The first RaF 340 and the second RaF 350 can be made of or from any suitable material. In some embodiments, the first RaF 340 can be made of or from a similar or the same material as the second metal layer 320. For example, the RaF 340 can be made of a heavy material. In some embodiments, the second RaF 350 can be made of or from a low acoustic impedance material. For example, the second RaF 350 can be made of silicon dioxide, silicon nitride, etc. The second RaF 350 may be made of any low density material.

The FBAR device 300 includes a passivation layer 390. The passivation layer 390 can be on top of the first RaF 340 and an exposed portion of the second metal layer 320. The exposed portion of the second metal layer 320 can be a portion that is not covered by the RaF 340. The passivation layer 390 can include an active region 360 and a ReF 395. The ReF 395 can be between the gradient RaF portion 344 of the RaF 340 and the active region 360. For example, the thickness of the ReF 395 may be less than the thickness of the active region 360. The ReF 395 can be recessed with respect to the active region 360. The thickness of the ReF 395 can be the same as the thickness of the passivation layer 390 over the non-gradient RaF portion 342 and the gradient RaF portion 344. In some embodiments, the ReF 395 can be a ring structure. In certain embodiments, the recessed frame 395 and/or the passivation layer 390 may be optional. The FBAR device 300 can include a substrate 370 and an air cavity 380 below the first metal layer 310.

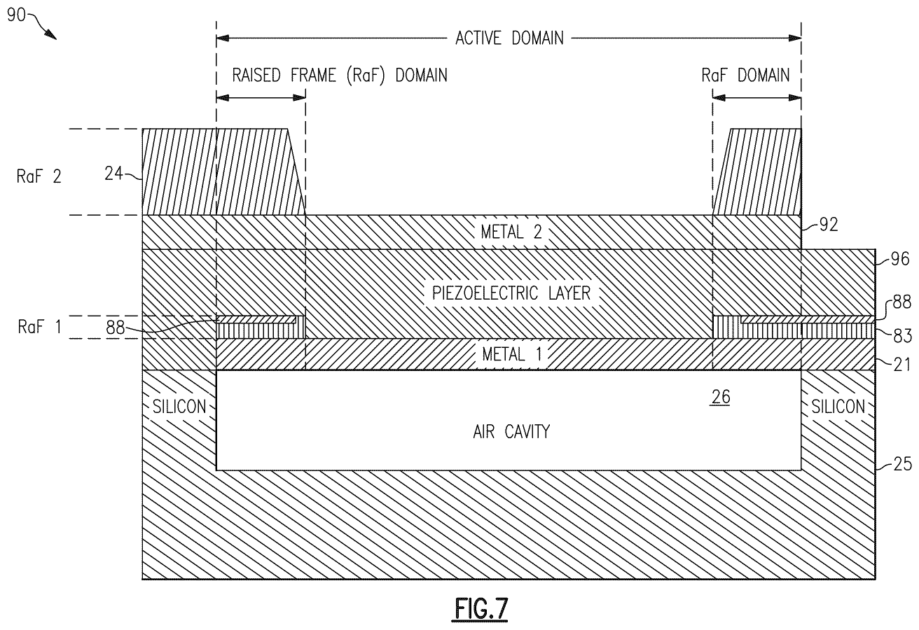

FIG. 10 illustrates a side view of a FBAR device 500 including two gradient raised frames 540, 550, according to certain embodiments. The FBAR device 500 can include a first metal layer 510, a second metal layer 520, and a piezoelectric layer 530 between the first metal layer 510 and the second metal layer 520. In the example of FIG. 10, the FBAR device 500 includes a first RaF 540 and a second RaF 550. The first RaF 540 can be on top of the second metal layer 520, and the second RaF 550 can be below the second metal layer 520, between the second metal layer 520 and the piezoelectric layer 530. The first RaF 540 can include a non-gradient RaF portion 542 and a gradient RaF portion 544. The gradient RaF portion 544 can have an angle α, for example, with respect to the horizontal direction. In some embodiments, the angle α can be less than 90°. The second RaF 550 can include a non-gradient RaF portion 552 and a gradient RaF portion 554. The gradient RaF portion 554 can also have an angle α, for example, with respect to the horizontal direction. In some embodiments, the angle α can be less than 90°. In some embodiments, the angle α for the gradient RaF portion 544 and the angle α for the gradient RaF portion 554 can be the same. In other embodiments, the angle α for the gradient RaF portion 544 and the angle α for the gradient RaF portion 554 can be different.

In the example of FIG. 10, the length of the gradient RaF portion 544 and the length of the gradient RaF portion 554 are the same. The second metal layer 520 can follow the contour of the gradient RaF portion 554. The gradient RaF portion 544 can follow the contour of the second metal layer 520. In the example of FIG. 10, the lower or bottom edge of the gradient RaF portion 544 can be parallel to the upper or top edge of the gradient RaF portion 554 and can be at an angle with respect to the horizontal direction. The lower or bottom edge of the gradient RaF portion 554 can be parallel to the horizontal direction. In the example of FIG. 5, the length of the non-gradient RaF portion 542 and the length of the non-gradient RaF portion 552 can be the same. The non-gradient RaF portion 542 and the non-gradient RaF portion 552 can be aligned. The non-tapering end of the gradient RaF portion 544 and the non-tapering end of the gradient RaF portion 554 can also be aligned. In some embodiments, the length of the non-gradient RaF portion 542 and the length of the non-gradient RaF portion 552 can be different. In certain embodiments, the thickness of the RaF 540 and the thickness of the RaF 550 can be the same. In other embodiments, the thickness of the RaF 540 and the thickness of the RaF 550 can be different.

Similar to the embodiments shown in FIGS. 8 and 9, a mass-loading layer 556 is disposed beneath the non-gradient RaF portion 552 of the second RaF 550 and on top of the piezoelectric layer 530. The mass-loading layer 556 may be implemented with the same properties and characteristics as the mass-loading layer 156 of FIG. 8 and/or the mass-loading layer 356 of FIG. 9.

The first RaF 540 and the second RaF 550 can be made of or from any suitable material. In some embodiments, the first RaF 540 can be made of or from a similar or the same material as the second metal layer 520. For example, the RaF 540 can be made of a heavy material. In some embodiments, the second RaF 550 can be made of or from a low acoustic impedance material. For example, the second RaF 550 can be made of silicon dioxide, silicon nitride, etc. The second RaF 550 may be made of any low density material. In the example of FIG. 10, the FBAR device 500 does not include a passivation layer or a recessed frame. In other embodiments, a FBAR device can include a passivation layer and/or a recessed frame. The FBAR device 500 can include an active region 560, for example, between the gradient RaF portion 544 of the first RaF 540 on each side of the FBAR device 500. The FBAR device 500 can include a substrate 570 and an air cavity 580 below the first metal layer 510.

FIG. 11 illustrates a side view of a FBAR device 600 including two gradient raised frames 640, 650, according to certain embodiments. The FBAR device 600 can include a first metal layer 610, a second metal layer 620, and a piezoelectric layer 630 between the first metal layer 610 and the second metal layer 620. In the example of FIG. 11, the FBAR device 600 includes a first RaF 640 and a second RaF 650. The first RaF 640 can be on top of the second metal layer 620, and the second RaF 650 can be below the second metal layer 620, between the second metal layer 620 and the piezoelectric layer 630. The first RaF 640 can include a non-gradient RaF portion 642 and a gradient RaF portion 644. The gradient RaF portion 644 can have an angle α, for example, with respect to the horizontal direction. In some embodiments, the angle α can be less than 90°. The second RaF 650 can include a non-gradient RaF portion 652 and a gradient RaF portion 654. The gradient RaF portion 654 can also have an angle α, for example, with respect to the horizontal direction. In some embodiments, the angle α can be less than 90°. In some embodiments, the angle α for the gradient RaF portion 644 and the angle α for the gradient RaF portion 654 can be the same. In other embodiments, the angle α for the gradient RaF portion 644 and the angle α for the gradient RaF portion 654 can be different.

In the example of FIG. 11, the length of the gradient RaF portion 644 is greater than the length of the gradient RaF portion 654. For instance, the gradient RaF portion 644 has a longer weight than the gradient RaF portion 654. The second metal layer 620 can follow the contour of the gradient RaF portion 654. The gradient RaF portion 644 can follow the contour of the second metal layer 620. In the example of FIG. 11, the lower or bottom edge of the gradient RaF portion 644 can be at an angle with respect to the horizontal direction. The lower or bottom edge of the gradient RaF portion 654 can be parallel to the horizontal direction. In the example of FIG. 11, the length of the non-gradient RaF portion 642 and the length of the non-gradient RaF portion 652 can be the same. The non-gradient RaF portion 642 and the non-gradient RaF portion 652 can be aligned. The non-tapering end of the gradient RaF portion 644 and the non-tapering end of the gradient RaF portion 654 can also be aligned. In some embodiments, the length of the non-gradient RaF portion 642 and the length of the non-gradient RaF portion 652 can be different. In certain embodiments, the thickness of the RaF 640 and the thickness of the RaF 650 can be the same. In other embodiments, the thickness of the RaF 640 and the thickness of the RaF 650 can be different.

Similar to the embodiments shown in FIGS. 8 to 10, a mass-loading layer 656 is disposed beneath the non-gradient RaF portion 652 of the second RaF 650 and on top of the piezoelectric layer 630. The mass-loading layer 656 may be implemented with the same properties and characteristics as the mass-loading layer 156 of FIG. 8, the mass-loading layer 356 of FIG. 9 and/or the mass-loading layer 556 of FIG. 10.

The first RaF 640 and the second RaF 650 can be made of or from any suitable material. In some embodiments, the first RaF 640 can be made of or from a similar or the same material as the second metal layer 620. For example, the RaF 640 can be made of a heavy material. In some embodiments, the second RaF 650 can be made of or from a low acoustic impedance material. For example, the second RaF 650 can be made of silicon dioxide, silicon nitride, etc. The second RaF 650 may be made of any low density material. In the example of FIG. 11, the FBAR device 600 does not include a passivation layer or a recessed frame. In other embodiments, a FBAR device can include a passivation layer and/or a recessed frame. The FBAR device 600 can include an active region 660, for example, between the gradient RaF portion 644 of the first RaF 640 on each side of the FBAR device 600. The FBAR device 600 can include a substrate 670 and an air cavity 680 below the first metal layer 610.

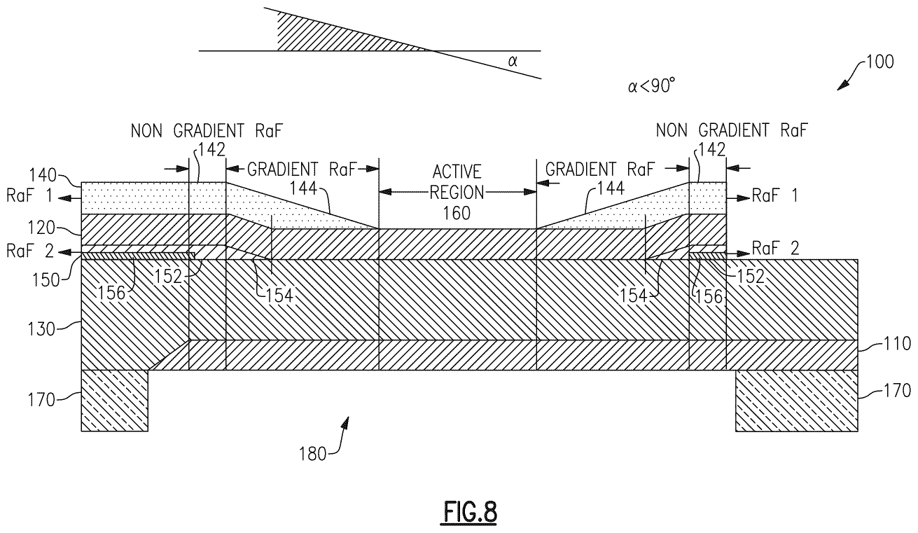

FIG. 12 illustrates a side view of a FBAR device 700 including two gradient raised frames 740, 750, according to certain embodiments. The FBAR device 700 can include a first metal layer 710, a second metal layer 720, and a piezoelectric layer 730 between the first metal layer 710 and the second metal layer 720. In the example of FIG. 12, the FBAR device 700 includes a first RaF 740 and a second RaF 750. The first RaF 740 can be on top of the second metal layer 720, and the second RaF 750 can be on top of the first metal layer 710, between the piezoelectric layer 730 and the first metal layer 710. The first RaF 740 can include a non-gradient RaF portion 742 and a gradient RaF portion 744. The gradient RaF portion 744 can have an angle α, for example, with respect to the horizontal direction. In some embodiments, the angle α can be less than 90°. The second RaF 750 can include a non-gradient RaF portion 752 and a gradient RaF portion 754. The gradient RaF portion 754 can also have an angle α, for example, with respect to the horizontal direction. In some embodiments, the angle α can be less than 90°. In some embodiments, the angle α for the gradient RaF portion 744 and the angle α for the gradient RaF portion 754 can be the same. In other embodiments, the angle α for the gradient RaF portion 744 and the angle α for the gradient RaF portion 754 can be different.

In the example of FIG. 12, the length of the gradient RaF portion 744 and the length of the gradient RaF portion 754 are the same. In the example of FIG. 12, the lower or bottom edge of the gradient RaF portion 744 can be parallel to the horizontal direction. The lower or bottom edge of the gradient RaF portion 754 can be parallel to the horizontal direction. The lower or bottom edge of the piezoelectric layer 730 can follow the contour of the second RaF 750. In the example of FIG. 12, the length of the non-gradient RaF portion 742 and the length of the non-gradient RaF portion 752 can be the same. The non-gradient RaF portion 742 and the non-gradient RaF portion 752 can be aligned. The non-tapering end of the gradient RaF portion 744 and the non-tapering end of the gradient RaF portion 754 can also be aligned. In some embodiments, the length of the non-gradient RaF portion 742 and the length of the non-gradient RaF portion 752 can be different. In certain embodiments, the thickness of the RaF 740 and the thickness of the RaF 750 can be the same. In other embodiments, the thickness of the RaF 740 and the thickness of the RaF 750 can be different.

Similar to the embodiments shown in FIGS. 8 to 11, a mass-loading layer 756 is disposed above or on top of the non-gradient RaF portion 752 of the second RaF 750 and beneath the piezoelectric layer 730. The mass-loading layer 756 may be implemented with the same properties and characteristics as the mass-loading layer 156 of FIG. 8, the mass-loading layer 356 of FIG. 9, the mass-loading layer 556 of FIG. 10, and/or the mass-loading layer 656 of FIG. 11. In particular, the contour of the mass-loading layer 756 may follow the contour of the lower or bottom edge of the piezoelectric layer 730.

The first RaF 740 and the second RaF 750 can be made of or from any suitable material. In some embodiments, the first RaF 740 can be made of or from a similar or the same material as the second metal layer 720. For example, the RaF 740 can be made of a heavy material. In some embodiments, the second RaF 750 can be made of or from a low acoustic impedance material. For example, the second RaF 750 can be made of silicon dioxide, silicon nitride, etc. The second RaF 750 may be made of any low density material. In certain embodiments, the second RaF 750 can be made of or from a similar or the same material as the second metal layer 720 and/or the first metal layer 710. In the example of FIG. 12, the FBAR device 700 does not include a passivation layer or a recessed frame. In other embodiments, a FBAR device can include a passivation layer and/or a recessed frame. The FBAR device 700 can include an active region 760, for example, between the gradient RaF portion 744 of the first RaF 740 on each side of the FBAR device 700. The FBAR device 700 can include a substrate 770 and an air cavity 780 below the first metal layer 710.

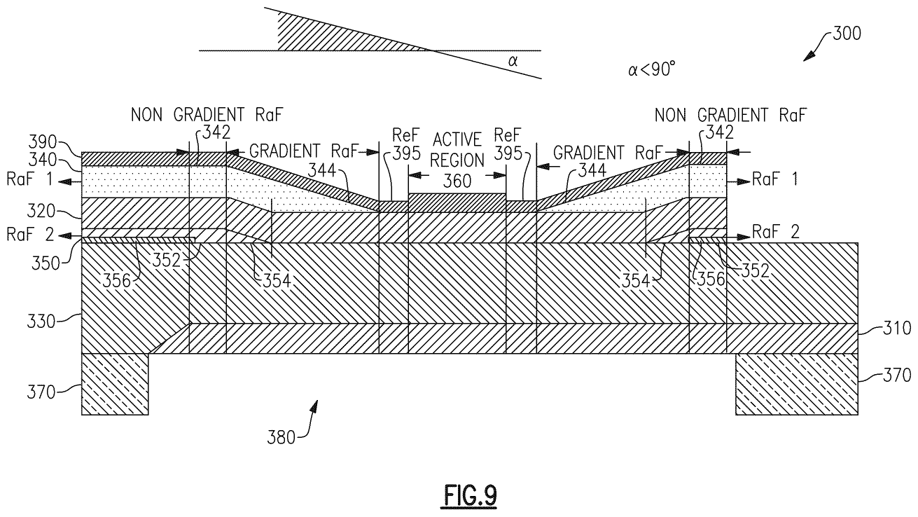

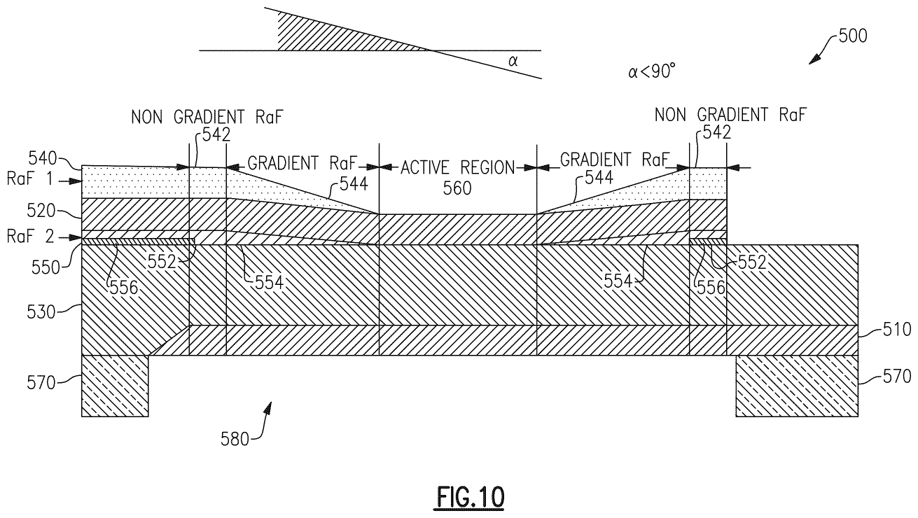

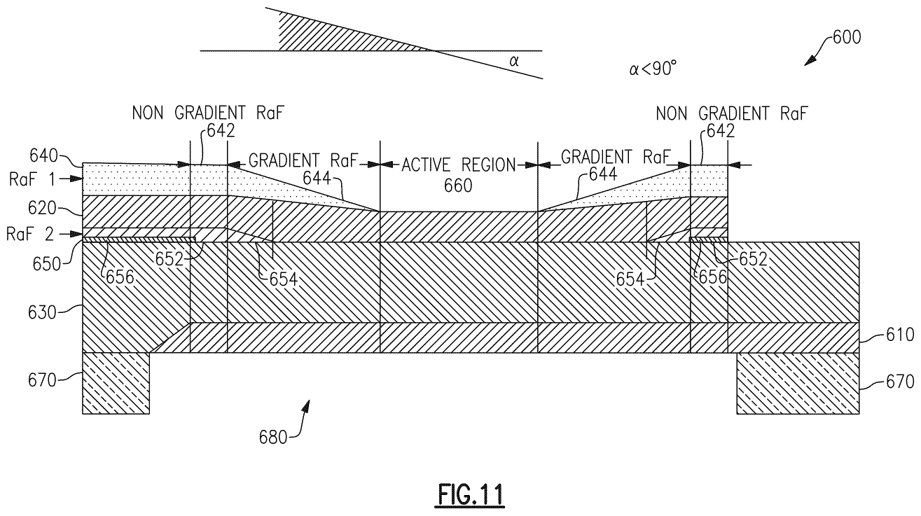

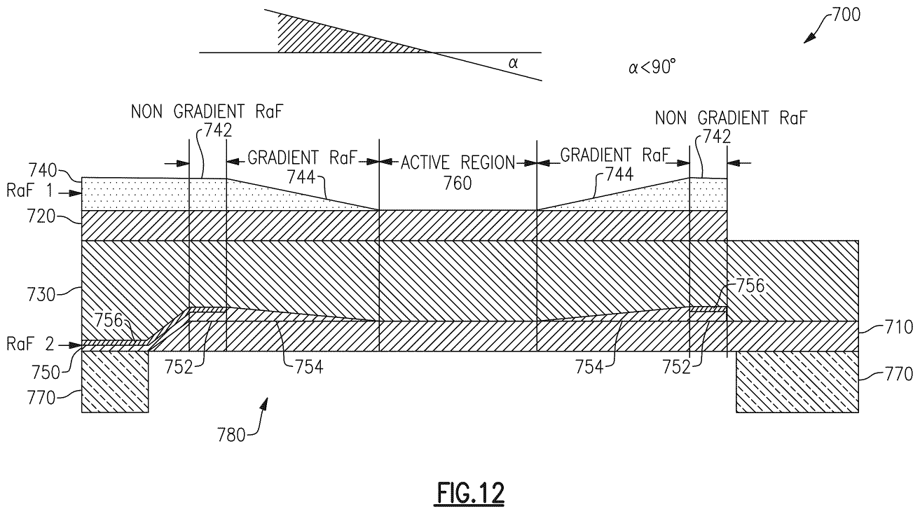

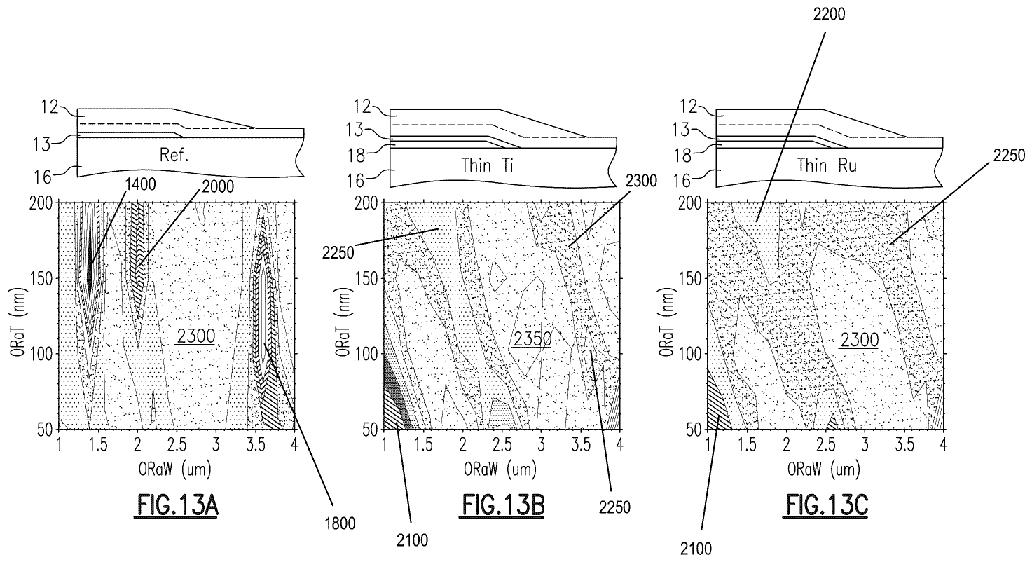

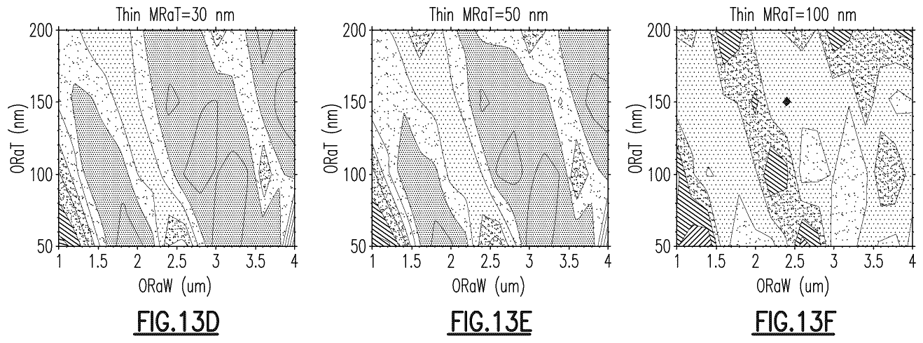

FIGS. 13A to 13C illustrates exemplary Q factor simulation results for a various implementations of dual raised frame bulk acoustic wave devices. FIG. 13A illustrates exemplary Q factor simulation results for a conventional dual raised frame bulk acoustic wave device. FIG. 13B illustrates exemplary Q factor simulation results for a dual raised frame bulk acoustic wave device with a Ti mass loading layer. FIG. 13C illustrates exemplary Q factor simulation results for a dual raised frame bulk acoustic wave device with a Ru mass loading layer.

As can be seen from the Q factor simulation results for a conventional dual raised frame bulk acoustic wave device in FIG. 13A having a silicon dioxide raised frame layer 13 between a metal electrode 12 and a piezoelectric layer 16, variations in slope and thickness of a silicon dioxide first raised frame layer 13 result in generally high Q across the varied parameters.

However, when compared with a dual raised frame bulk acoustic wave device in FIG. 13B having a thin mass-loading layer 18 made from titanium (Ti) disposed beneath the silicon dioxide first raised frame layer 13 and the piezoelectric layer 16, variations in slope and thickness of a silicon dioxide first raised frame layer 13 result in even higher Q across the varied parameters over the conventional dual raised frame bulk acoustic wave device in FIG. 13A. The simulation results indicate that the simulated BAW device can achieve a higher Q.

Similarly, for the dual raised frame bulk acoustic wave device in FIG. 13C having a thin mass-loading layer 18 made from ruthenium (Ru) disposed beneath the silicon dioxide first raised frame layer 13 and the piezoelectric layer 16, variations in slope and thickness of a silicon dioxide first raised frame layer 13 also result in even higher Q across the varied parameters over the conventional dual raised frame bulk acoustic wave device in FIG. 13A. The simulation results indicate that the simulated BAW device 40 can achieve a higher Q.

FIGS. 13D to 13F illustrate exemplary Q factor simulation results for dual raised frame bulk acoustic wave devices with a Ti mass loading layer 18 of various thicknesses. The overall thickness of the raised frame layer 13 together with the mass-loading layer 18 is 220 nm in those exemplary Q factor simulations. FIG. 13D illustrates exemplary Q factor simulation results for a dual raised frame bulk acoustic wave device with a Ti mass loading layer having a thickness of 25 nm. FIG. 13E illustrates exemplary Q factor simulation results for a dual raised frame bulk acoustic wave device with a Ti mass loading layer having a thickness of 50 nm. FIG. 13F illustrates exemplary Q factor simulation results for a dual raised frame bulk acoustic wave device with a Ti mass loading layer having a thickness of 100 nm. In every case, a generally higher Q may be achieved in comparison to a similar dual raised frame bulk acoustic wave device lacking a mass-loading layer.

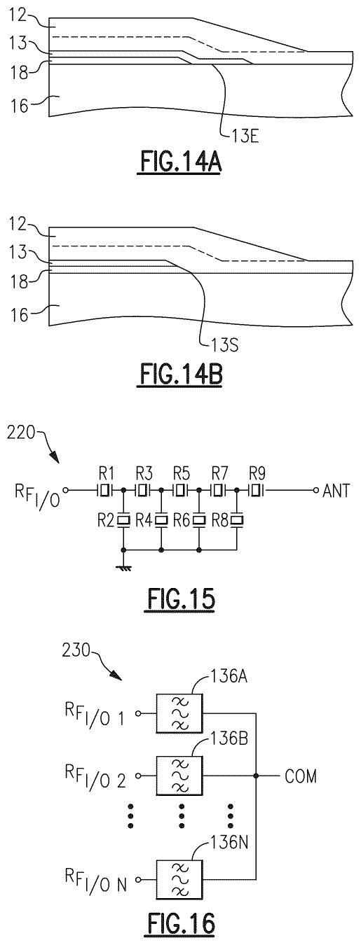

FIG. 14A is a cross sectional view of a dual raised frame bulk acoustic wave device with an extended raised frame layer. The dual raised frame bulk acoustic wave device in FIG. 14A has a thin mass-loading layer 18 disposed beneath the first raised frame layer 13 and the piezoelectric layer 16. The thin mass-loading layer 18 may be embodied similar to the mass-loading layers as illustrated and explained in conjunction with any of the FIGS. 1 to 12. The raised frame layer 13 may have an extended portion 13E extending into the active domain of the raised frame bulk acoustic wave device.

FIG. 14B is a cross sectional view of a dual raised frame bulk acoustic wave device with a slanted raised frame layer. The dual raised frame bulk acoustic wave device in FIG. 14B has a thin mass-loading layer 18 disposed beneath the first raised frame layer 13 and the piezoelectric layer 16. The thin mass-loading layer 18 may be embodied similar to the mass-loading layers as illustrated and explained in conjunction with any of the FIGS. 1 to 12. The raised frame layer 13 may have a slanted edge 13S that partially exposes the thin mass-loading layer 18 to the metal electrode 12 towards the active domain of the raised frame bulk acoustic wave device.

The multi-layer or dual raised frame bulk acoustic wave resonators disclosed herein can be implemented in acoustic wave filters. In certain applications, the acoustic wave filters can be band pass filters arranged to pass a radio frequency band and attenuate frequencies outside of the radio frequency band. Two or more acoustic wave filters can be coupled together at a common node and arranged as a multiplexer, such as a duplexer.

FIG. 15 is a schematic diagram of an example of an acoustic wave ladder filter 220. The acoustic wave ladder filter 220 can be a transmit filter or a receive filter. The acoustic wave ladder filter 220 can be a band pass filter arranged to filter a radio frequency signal. The acoustic wave filter 220 includes series resonators R1, R3, R5, R7, and R9 and shunt resonators R2, R4, R6, and R8 coupled between a radio frequency input/output port RFI/O and an antenna port ANT. The radio frequency input/output port RFI/O can be a transmit port in a transmit filter or a receive port in a receive filter. One or more of the illustrated acoustic wave resonators can be a multi-layer or dual raised frame bulk acoustic wave resonator in accordance with any suitable principles and advantages discussed herein. An acoustic wave ladder filter can include any suitable number of series resonators and any suitable number of shunt resonators.

An acoustic wave filter can be arranged in any other suitable filter topology, such as a lattice topology or a hybrid ladder and lattice topology. A bulk acoustic wave resonator in accordance with any suitable principles and advantages disclosed herein can be implemented in a band pass filter. In some other applications, a bulk acoustic wave resonator in accordance with any suitable principles and advantages disclosed herein can be implemented in a band stop filter.

FIG. 16 is a schematic diagram of a multiplexer 230 that includes an acoustic wave filter according to an embodiment. The multiplexer 230 includes a plurality of filters 136A to 136N coupled together at a common node COM. The plurality of filters can include any suitable number of filters including, for example, 3 filters, 4 filters, 5 filters, 6 filters, 7 filters, 8 filters, or more filters. Some or all of the plurality of acoustic wave filters can be acoustic wave filters. Each of the illustrated filters 136A, 136B, and 136N is coupled between the common node COM and a respective input/output node RFI/O1, RFI/O2, and RFI/ON.

In some instances, all filters of the multiplexer 230 can be receive filters. According to some other instances, all filters of the multiplexer 230 can be transmit filters. In various applications, the multiplexer 230 can include one or more transmit filters and one or more receive filters. Accordingly, the multiplexer 230 can include any suitable number of transmit filters and any suitable number of receive filters. Each of the illustrated filters can be band pass filters having different respective pass bands.

The multiplexer 230 is illustrated with hard multiplexing with the filters 136A to 136N having fixed connections to the common node COM. In some other applications, one or more of the filters of a multiplexer can be electrically connected to the common node by a respective switch. Any of such filters can include a bulk acoustic wave resonator according to any suitable principles and advantages disclosed herein.

A first filter 136A is an acoustic wave filter having a first pass band and arranged to filter a radio frequency signal. The first filter 136A can include one or more bulk acoustic wave resonators according to any suitable principles and advantages disclosed herein. A second filter 136B has a second pass band. A multi-layer raised frame structure of one or more bulk acoustic wave resonators of the first filter 136A can move a raised frame mode of the one or more bulk acoustic wave resonators away from the second passband. This can increase a reflection coefficient (Gamma) of the first filter 136A in the pass band of the second filter 136B. The multi-layer raised frame structure of the bulk acoustic wave resonator of the first filter 136A also move the raised frame mode away from the passband of one or more other filters of the multiplexer 230.

In certain instances, the common node COM of the multiplexer 230 is arranged to receive a carrier aggregation signal including at least a first carrier associated with the first passband of the first filter 136A and a second carrier associated with the second passband of the second filter 136B. A multi-layer raised frame structure of a bulk acoustic wave resonator of the first filter 136A can maintain and/or increase a reflection coefficient of the first filter 136A in the second passband of the second filter 136B that is associated with the second carrier of the carrier aggregation signal.

The filters 136B to 136N of the multiplexer 230 can include one or more acoustic wave filters, one or more acoustic wave filters that include at least one bulk acoustic wave resonator with a multi-layer raised frame structure, one or more LC filters, one or more hybrid acoustic wave LC filters, or any suitable combination thereof.

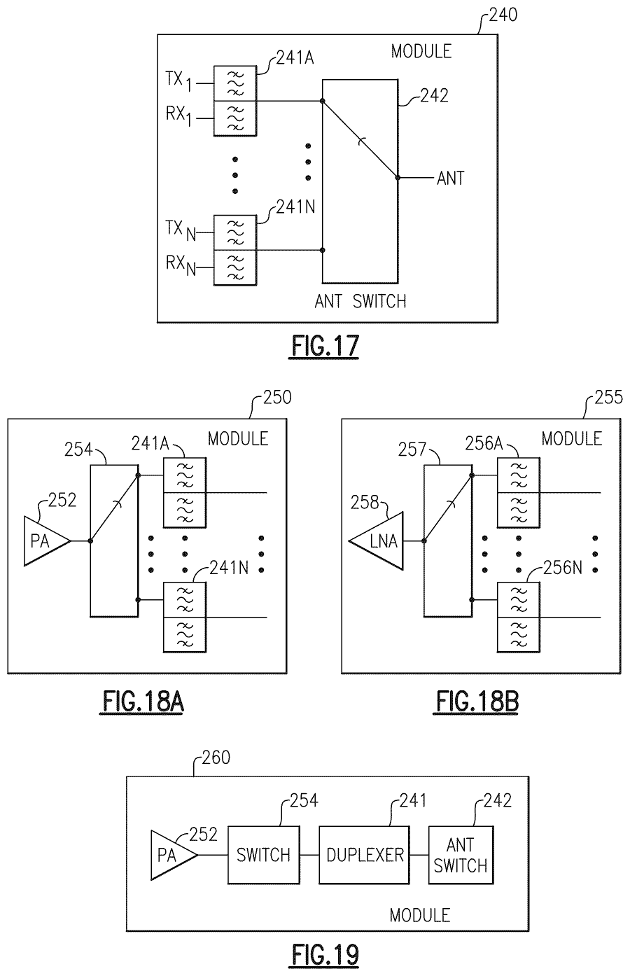

The multi-layer raised frame bulk acoustic wave resonators disclosed herein can be implemented in a variety of packaged modules. Some example packaged modules will now be discussed in which any suitable principles and advantages of the bulk acoustic wave devices disclosed herein can be implemented. The example packaged modules can include a package that encloses the illustrated circuit elements. The illustrated circuit elements can be disposed on a common packaging substrate. The packaging substrate can be a laminate substrate, for example. FIGS. 17, 18A, 18B, and 19 are schematic block diagrams of illustrative packaged modules according to certain embodiments. Certain example packaged modules include one or more radio frequency amplifiers, such as one or more power amplifiers and/or one or more low noise amplifiers. Any suitable combination of features of these modules can be implemented with each other. While duplexers are illustrated in the example packaged modules of FIGS. 17, 18A, and 19, any other suitable multiplexer that includes a plurality of acoustic wave filters coupled to a common node can be implemented instead of one or more duplexers. For example, a quadplexer can be implemented in certain applications. Alternatively or additionally, one or more filters of a packaged module can be arranged as a transmit filter or a receive filter that is not included in a multiplexer.

FIG. 17 is a schematic block diagram of a module 240 that includes duplexers 241A to 241N and an antenna switch 242. One or more filters of the duplexers 241A to 241N can include any suitable number of multi-layer or dual raised frame bulk acoustic wave resonators in accordance with any suitable principles and advantages discussed herein. Any suitable number of duplexers 241A to 241N can be implemented. The antenna switch 242 can have a number of throws corresponding to the number of duplexers 241A to 241N. The antenna switch 242 can electrically couple a selected duplexer to an antenna port of the module 240.

FIG. 18A is a schematic block diagram of a module 250 that includes a power amplifier 252, a radio frequency switch 254, and duplexers 241A to 241N in accordance with one or more embodiments. The power amplifier 252 can amplify a radio frequency signal. The radio frequency switch 254 can be a multi-throw radio frequency switch. The radio frequency switch 254 can electrically couple an output of the power amplifier 252 to a selected transmit filter of the duplexers 241A to 241N. One or more filters of the duplexers 241A to 241N can include any suitable number of multi-layer raised frame bulk acoustic wave resonators in accordance with any suitable principles and advantages discussed herein. Any suitable number of duplexers 241A to 241N can be implemented.

FIG. 18B is a schematic block diagram of a module 255 that includes filters 256A to 256N, a radio frequency switch 257, and a low noise amplifier 258 according to an embodiment. One or more filters of the filters 256A to 256N can include any suitable number of multi-layer or dual raised frame bulk acoustic wave resonators in accordance with any suitable principles and advantages disclosed herein. Any suitable number of filters 256A to 256N can be implemented. The illustrated filters 256A to 256N are receive filters. In some embodiments (not illustrated), one or more of the filters 256A to 256N can be included in a multiplexer that also includes a transmit filter. The radio frequency switch 257 can be a multi-throw radio frequency switch. The radio frequency switch 257 can electrically couple an output of a selected filter of filters 256A to 256N to the low noise amplifier 257. In some embodiments (not illustrated), a plurality of low noise amplifiers can be implemented. The module 255 can include diversity receive features in certain applications.

FIG. 19 is a schematic block diagram of a module 260 that includes a power amplifier 252, a radio frequency switch 254, and a duplexer 241 that includes a multi-layer or dual raised frame bulk acoustic wave device in accordance with one or more embodiments, and an antenna switch 242. The module 260 can include elements of the module 240 and elements of the module 250.

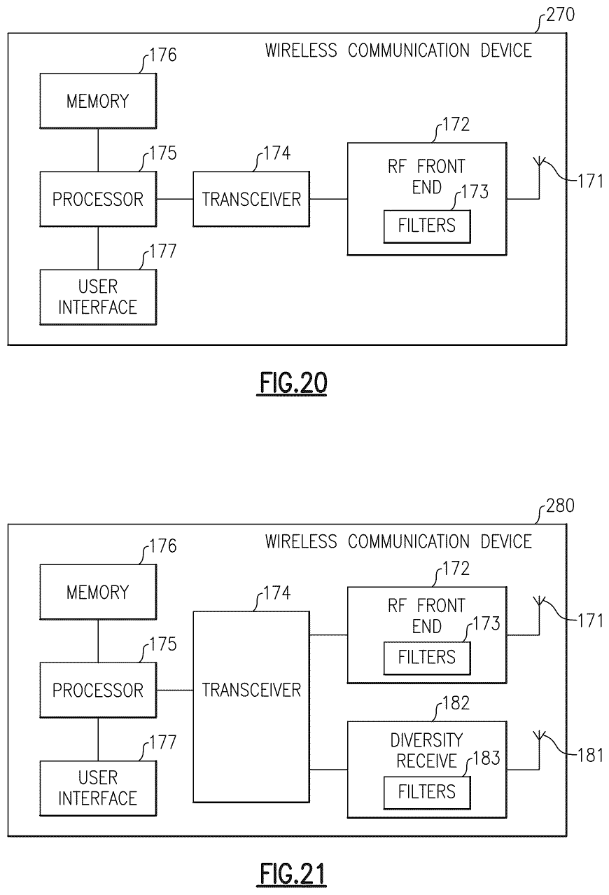

One or more filters with any suitable number of multi-layer raised frame bulk acoustic devices can be implemented in a variety of wireless communication devices. FIG. 20 is a schematic block diagram of a wireless communication device 270 that includes a filter 173 with one or more multi-layer raised frame bulk acoustic wave resonators in accordance with any suitable principles and advantages disclosed herein. The wireless communication device 270 can be any suitable wireless communication device. For instance, a wireless communication device 270 can be a mobile phone, such as a smart phone. As illustrated, the wireless communication device 270 includes an antenna 171, a radio frequency (RF) front end 172 that includes filter 173, an RF transceiver 174, a processor 175, a memory 176, and a user interface 177. The antenna 171 can transmit RF signals provided by the RF front end 172. The antenna 171 can provide received RF signals to the RF front end 172 for processing.

The RF front end 172 can include one or more power amplifiers, one or more low noise amplifiers, RF switches, receive filters, transmit filters, duplex filters, filters of a multiplexer, filters of a diplexers or other frequency multiplexing circuit, or any suitable combination thereof. The RF front end 172 can transmit and receive RF signals associated with any suitable communication standards. Any of the multi-layer raised frame bulk acoustic wave resonators disclosed herein can be implemented in filters 173 of the RF front end 172.

The RF transceiver 174 can provide RF signals to the RF front end 172 for amplification and/or other processing. The RF transceiver 174 can also process an RF signal provided by a low noise amplifier of the RF front end 172. The RF transceiver 174 is in communication with the processor 175. The processor 175 can be a baseband processor. The processor 175 can provide any suitable base band processing functions for the wireless communication device 170. The memory 176 can be accessed by the processor 175. The memory 176 can store any suitable data for the wireless communication device 270. The processor 175 is also in communication with the user interface 177. The user interface 177 can be any suitable user interface, such as a display.

FIG. 21 is a schematic diagram of a wireless communication device 280 that includes filters 173 in a radio frequency front end 172 and second filters 183 in a diversity receive module 182. The wireless communication device 280 is like the wireless communication device 270 of FIG. 20, except that the wireless communication device 280 also includes diversity receive features. As illustrated in FIG. 21, the wireless communication device 280 includes a diversity antenna 181, a diversity module 182 configured to process signals received by the diversity antenna 181 and including filters 183, and a transceiver 174 in communication with both the radio frequency front end 172 and the diversity receive module 182. One or more of the second filters 183 can include a bulk acoustic wave resonator with a multi-layer or dual raised frame structure in accordance with any suitable principles and advantages disclosed herein.

Bulk acoustic wave devices disclosed herein can be included in a filter and/or a multiplexer arranged to filter a radio frequency signal in a fifth generation (5G) New Radio (NR) operating band within Frequency Range 1 (FR1). FR1 can from 410 megahertz (MHz) to 7.125 gigahertz (GHz), for example, as specified in a current 5G NR specification. A filter arranged to filter a radio frequency signal in a 5G NR FR1 operating band can include one or more bulk acoustic wave resonators be implemented in accordance with any suitable principles and advantages disclosed herein.

5G NR carrier aggregation specifications can present technical challenges. For example, 5G carrier aggregations can have wider bandwidth and/or channel spacing than fourth generation (4G) Long Term Evolution (LTE) carrier aggregations. Carrier aggregation bandwidth in certain 5G FR1 applications can be in a range from 120 MHz to 400 MHz, such as in a range from 120 MHz to 200 MHz. Carrier spacing in certain 5G FR1 applications can be up to 100 MHz. Bulk acoustic wave resonators with a multi-layer or dual raised frame structure disclosed herein can achieve low insertion loss and low Gamma loss. The frequency of a raised frame mode of such a bulk acoustic wave resonator can be moved significantly away from a resonant frequency of the bulk acoustic wave resonator. Accordingly, the raised frame mode can be outside of a carrier aggregation band even with the wider carrier aggregation bandwidth and/or channel spacing within FR1 in 5G specifications. This can reduce and/or eliminate Gamma degradation in an operating band of another carrier of a carrier aggregation. In some instances, Gamma can be increased in the operating band of the other carrier of the carrier aggregation.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a frequency range from about 30 kHz to 300 GHz, such as in a frequency range from about 450 MHz to 8.5 GHz.

Aspects of this disclosure can be implemented in various electronic devices. Examples of the electronic devices can include, but are not limited to, consumer electronic products, parts of the consumer electronic products such as packaged radio frequency modules, radio frequency filter die, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a robot such as an industrial robot, an Internet of things device, a stereo system, a digital music player, a radio, a camera such as a digital camera, a portable memory chip, a home appliance such as a washer or a dryer, a peripheral device, a wrist watch, a clock, etc. Further, the electronic devices can include unfinished products.

Unless the context indicates otherwise, throughout the description and the claims, the words “comprise,” “comprising,” “include,” “including” and the like are to generally be construed in an inclusive sense, as opposed to an exclusive or exhaustive sense; that is to say, in the sense of “including, but not limited to.” Conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. The word “coupled”, as generally used herein, refers to two or more elements that may be either directly coupled, or coupled by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively.

While certain embodiments have been described, these embodiments have been presented by way of example only, and are not intended to limit the scope of the disclosure. Indeed, the novel resonators, filters, multiplexer, devices, modules, wireless communication devices, apparatus, methods, and systems described herein may be embodied in a variety of other forms. Furthermore, various omissions, substitutions and changes in the form of the resonators, filters, multiplexer, devices, modules, wireless communication devices, apparatus, methods, and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and/or acts of the various embodiments described above can be combined to provide further embodiments. The accompanying claims and their equivalents are intended to cover such forms or modifications as would fall within the scope and spirit of the disclosure.

What is claimed is:

1. A bulk acoustic wave device comprising:
a first electrode, a second electrode, and a piezoelectric layer positioned between the first electrode and the second electrode;
a first raised frame structure outside of a middle area of an active domain of the bulk acoustic wave device, the raised frame structure including a first raised frame layer positioned between the first electrode and the second electrode and having a lower acoustic impedance than the first electrode; and
a mass-loading layer disposed between the first raised frame layer and the piezoelectric layer, the thickness of the mass-loading layer being less than 50% of the thickness of the first raised frame layer, the first raised frame layer extending further into the active domain of the bulk acoustic wave device than the mass-loading layer.

2. The bulk acoustic wave device of claim 1 wherein the first raised frame layer is a silicon dioxide layer.

3. The bulk acoustic wave device of claim 1 wherein the acoustic impedance of the first raised frame layer is lower than an acoustic impedance of the piezoelectric layer.

4. The bulk acoustic wave device of claim 1 wherein the first electrode includes at least one of molybdenum, tungsten, ruthenium, platinum, or iridium.

5. The bulk acoustic wave device of claim 1 wherein the first raised frame layer is positioned between the piezoelectric layer and the first electrode.

6. The bulk acoustic wave device of claim 1 wherein the mass-loading layer includes at least one of titanium, ruthenium, molybdenum, tungsten, platinum, aluminum, iridium, chromium, cobalt, nickel, copper, gold, or any suitable alloy thereof.

7. The bulk acoustic wave device of claim 1 wherein the mass-loading layer includes at least one of aluminum oxide, silicon carbide, aluminum nitride, titanium nitride, silicon nitride, silicon oxynitride, or diamond like carbon.

8. A multiplexer comprising:
a first filter having a first passband, the first filter including a bulk acoustic wave device, the bulk acoustic wave device including a raised frame structure outside of a middle area of an active region of the bulk acoustic wave device, the raised frame structure including a first raised frame layer positioned between an electrode and a piezoelectric layer, the first raised frame layer having a lower acoustic impedance than the electrode, and a mass-loading layer disposed between the first raised frame layer and the piezoelectric layer, the thickness of the mass-loading layer being less than 50% of the thickness of the first raised frame layer, the first raised frame layer extending further into the active domain of the bulk acoustic wave device than the mass-loading layer; and
a second filter having a second passband, the second filter coupled to the first filter at a common node, and the raised frame structure configured to move a raised frame mode of the bulk acoustic wave device away from the second passband.

9. The multiplexer of claim 9 wherein the common node is configured to receive a carrier aggregation signal including at least a first carrier associated with the first passband and a second carrier associated with the second passband.

10. The multiplexer of claim 9 wherein the electrode includes at least one of molybdenum, tungsten, ruthenium, platinum, or iridium.

11. The multiplexer of claim 9 wherein the mass-loading layer includes at least one of titanium, ruthenium, molybdenum, tungsten, platinum, aluminum, iridium, chromium, cobalt, nickel, copper, gold, or any suitable alloy thereof.

12. The multiplexer of claim 9 wherein the mass-loading layer includes at least one of aluminum oxide, silicon carbide, aluminum nitride, titanium nitride, silicon nitride, silicon oxynitride, or diamond like carbon.

13. A packaged module comprising:
a packaging substrate;
an acoustic wave filter on the packaging substrate and configured to filter a radio frequency signal, the acoustic wave filter including a bulk acoustic wave device, the bulk acoustic wave device including a raised frame structure outside of a middle area of an active region of the bulk acoustic wave device, the raised frame structure including a first raised frame layer positioned between an electrode and a piezoelectric layer, the first raised frame layer having a lower acoustic impedance than the electrode, and a mass-loading layer disposed between the first raised frame layer and the piezoelectric layer, the thickness of the mass-loading layer being less than 50% of the thickness of the first raised frame layer, the first raised frame layer extending further into the active domain of the bulk acoustic wave device than the mass-loading layer; and
a radio frequency component electrically coupled to the acoustic wave filter and positioned on the packaging substrate, the acoustic wave filter and the radio frequency component being enclosed within a common package.

14. A film bulk acoustic wave resonator device comprising:
a substrate;
first and second metal layers implemented over the substrate;
a piezoelectric layer between the first and second metal layers; and
a gradient raised frame structure outside of a middle area of an active domain of the bulk acoustic wave device, the gradient raised frame structure including a first raised frame layer positioned between the first electrode and the second electrode, having a lower acoustic impedance than the first electrode, and having a non-gradient portion and a gradient portion; and
a mass-loading layer disposed between the non-gradient portion of the first raised frame layer and the piezoelectric layer, the thickness of the mass-loading layer being less than 50% of the thickness of the non-gradient portion of the first raised frame layer, the first raised frame layer extending further into the active domain of the bulk acoustic wave device than the mass-loading layer.

15. The film bulk acoustic wave resonator device of claim 16 wherein the first raised frame layer is a silicon dioxide layer.

16. The film bulk acoustic wave resonator device of claim 16 wherein the acoustic impedance of the first raised frame layer is lower than an acoustic impedance of the piezoelectric layer.

17. The film bulk acoustic wave resonator device of claim 16 wherein the mass-loading layer includes at least one of titanium, ruthenium, molybdenum, tungsten, platinum, aluminum, iridium, chromium, cobalt, nickel, copper, gold, or any suitable alloy thereof.

18. The film bulk acoustic wave resonator device of claim 16 wherein the mass-loading layer includes at least one of aluminum oxide, silicon carbide, aluminum nitride, titanium nitride, silicon nitride, silicon oxynitride, or diamond like carbon.
